(19) United States
(12) Patent Application Publication
(10) Pub. No.: US 2006/0270186 A1
(43) Pub. Date: Nov. 30, 2006

(54) Semiconductor device having plural bird's beaks of different sizes and manufacturing method thereof

(76) Inventors: Takaaki Tsunomura, Tokyo (JP); Jun Sumino, Tokyo (JP)

Correspondence Address: MCDERMOTT WILL & EMERY LLP, 600 13TH STREET, N.W., WASHINGTON, DC, 20005-3096, US

(21) Appl. No.: 11/215,120

(22) Filed: Aug. 31, 2005

(30) Foreign Application Priority Data
Sep. 2, 2004 (JP) JP2004-255422
Jul. 22, 2005 (JP) JP2005-212719

(51) Int. Cl. H01L 29/94; H01L 21/76

(52) U.S. Cl. 438/439; 257/368

(57) ABSTRACT

First bird's beaks are respectively formed in first thermal oxide films at the bottom surface ends and the upper surface ends of a floating gate. In addition, second bird's beaks are formed in second thermal oxide films at the bottom surface ends of a control gate. The dimension of the first thermal oxide films in a gate length direction is smaller than the dimension of the second thermal oxide films in the gate length direction. The first bird's beaks are smaller than the second bird's beaks. In addition, the first bird's beaks are smaller than third bird's beaks (FIG. 12) which are formed in third thermal oxide films at the bottom surface ends of the gate electrode (polysilicon film) of a transistor for a peripheral circuit.

### BACKGROUND OF THE INVENTION

1. Field of the Invention

The present invention relates to a semiconductor device and a manufacturing method thereof. In particular, the present invention relates to a nonvolatile semiconductor memory device where memory cell transistors and transistors for a peripheral circuit are formed using the same semiconductor substrate, and a manufacturing method thereof.

2. Description of the Background Art

According to a conventional manufacturing method of a nonvolatile semiconductor memory device where memory cell transistors and transistors for a peripheral circuit are formed using the same semiconductor substrate, the respective side surfaces of floating gates and control gates of the memory cell transistors and the side surfaces of the gate electrodes of the transistors for the peripheral circuit are thermally oxidized in the same process for the purpose of alleviation of the electrical field at the gate ends and recovery of the thickness of the oxide film on the substrate that has been reduced through gate etching. Therefore, the size of the bird's beaks in the thermal oxide films that are formed in the respective side surfaces of the floating gates and the control gates and the size of the bird's beaks in the thermal oxide films that are formed in the side surfaces of the gate electrodes are equal to each other.

Here, a manufacturing method of a semiconductor device where memory cell transistors and transistors for a peripheral circuit are formed using the same semiconductor substrate is disclosed, for example, in Japanese Patent Application Laid-Open No. 2003-68889.

When the gate length of the transistors becomes short together with the miniaturization of a semiconductor device, the ratio of the length occupied by bird's beaks in the thermal oxide films along the entire length of the gate becomes relatively large. As a result, the thickness of the gate insulating film becomes effectively large. Therefore, in the case where the gate length becomes 0.20 μm or less in the memory cell transistors as the semiconductor device is miniaturized, the transistor characteristics deteriorate, e.g., the lead current reduces. On the other hand, a high voltage (5 to 40 V) is applied to the gate electrodes of the transistors for the peripheral circuit. Therefore, it is necessary to make the bird's beaks large and to suppress the concentration of the electrical field in the gate edges.

According to a conventional semiconductor device and a manufacturing method thereof, however, bird's beaks are equal to each other in the memory cell transistors and the transistors for a peripheral circuit. Therefore, small bird's beaks that are required in the memory cell transistors and large bird's beaks that are required in the transistors for the peripheral circuits are not compatible. As a result, a problem arises where concentration of the electrical field in the gate edges of the transistors for the peripheral circuit cannot be avoided while preventing deterioration in the transistor characteristics of the memory cell transistors.

### SUMMARY OF THE INVENTION

An object of the present invention is to provide a semiconductor device where bird's beaks in thermal oxide films are made to be different from each other between memory cell transistors and transistors for a peripheral circuit, so that both deterioration in transistor characteristics of the memory cell transistors and concentration of the electrical field at the gate edges of the transistors for the peripheral circuit can be avoided, as well as a manufacturing method thereof.

According to a first aspect of the present invention, a semiconductor device includes a semiconductor substrate, a first transistor and a second transistor. The semiconductor substrate has a memory cell array region and a peripheral circuit region. The first transistor is formed in the memory cell array region. The second transistor is formed in the peripheral circuit region. The first transistor includes a floating gate formed on an upper surface of the semiconductor substrate via a first insulating film, a control gate formed on the floating gate via a second insulating film, and a first thermal oxide film formed in a side surface of the floating gate. The second transistor includes a gate electrode formed on the upper surface of the semiconductor substrate via a third insulating film, and a second thermal oxide film formed in a side surface of the gate electrode. A bird's beak in the first thermal oxide film is smaller than a bird's beak in the second thermal oxide film.

Both deterioration in transistor characteristics of the first transistor formed in the memory cell array region and concentration of the electrical field at the gate edges of the second transistor formed in the peripheral circuit region can be avoided.

According to a second aspect of the present invention, a manufacturing method of a semiconductor device includes the following steps (a) to (h). In the step (a), a semiconductor substrate which has a memory cell array region where a first transistor is to be formed and a peripheral circuit region where a second transistor is to be formed is prepared. In the step (b), a first insulating film, a first conductive film and a second insulating film are formed in this order on an upper surface of the semiconductor substrate in the memory cell array region. In the step (c), a third insulating film is formed on the upper surface of the semiconductor substrate in the peripheral circuit region. In the step (d), a control gate of the first transistor is formed partially on the second insulating film and, also, a gate electrode of the second transistor is formed on the third insulating film. In the step (e), a first thermal oxide film having a first bird's beak is formed in a side surface of the gate electrode. The step (f) is carried out after completion of the step (e). In the step (f), a first sidewall insulating film made of a material having an oxygen blocking property is formed on the side surface of the control gate and, also, a second sidewall insulating film made of the material is formed on the side surface of the gate electrode. In the step (g), the first conductive film and the second insulating film are removed from the portion which is not covered with the first sidewall insulating film and the control gate. The portion of the first conductive film that is not removed in the step (g) becomes a floating gate of the first transistor. In the step (h), a second thermal oxide film having a second bird's beak which is smaller than the first bird's beak is formed in a side surface of the floating gate.

Both deterioration in transistor characteristics of the first transistor formed in the memory cell array region and concentration of the electrical field at the gate edges of the second transistor formed in the peripheral circuit region can be avoided.

According to a third aspect of the present invention, a manufacturing method of a semiconductor device includes the following steps (a) to (i). In the step (a), a semiconductor substrate which has a memory cell array region where a first transistor is to be formed and a peripheral circuit region where a second transistor is to be formed is prepared. In the step (b), a first insulating film, a first conductive film, a second insulating film and a second conductive film are formed in this order on an upper surface of the semiconductor substrate in the memory cell array region. In the step (c), a third insulating film and a third conductive film are formed in this order on the upper surface of the semiconductor substrate in the peripheral circuit region. In the step (d), a first film is formed partially on the second conductive film, and a second film is formed partially on the third conductive film. In the step (e), the portion of the third conductive film that is not covered with the second film is removed. The portion of the third conductive film that is not removed in the step (e) becomes a gate electrode of the second transistor. In the step (f), a first thermal oxide film having a first bird's beak is formed in a side surface of the gate electrode. The step (g) is carried out after completion of the step (f). In the step (g), a first sidewall insulating film made of a material having an oxygen blocking property is formed on the side surface of the first film and, also, a second sidewall insulating film made of the material is formed on the side surface of the gate electrode. In the step (h), the first conductive film, the second insulating film and the second conductive film are removed from the portion which is not covered with the first sidewall insulating film and the first film. The portion of the first conductive film that is not removed in the step (h) becomes a floating gate of the first transistor, and the portion of the second conductive film that is not removed in the step (h) becomes a control gate of the first transistor. In the step (i), a second thermal oxide film having a second bird's beak which is smaller than the first bird's beak is formed in a side surface of the floating gate.

Both deterioration in transistor characteristics of the first transistor formed in the memory cell array region and concentration of the electrical field at the gate edges of the second transistor formed in the peripheral circuit region can be avoided.

According to a fourth aspect of the present invention, a manufacturing method of a semiconductor device includes the following steps (a) to (k). In the step (a), a semiconductor substrate which has a memory cell array region where a first transistor is to be formed, a high-voltage system peripheral circuit region where a second transistor driven by a high voltage is to be formed, and a low-voltage system peripheral circuit region where a third transistor driven by a low voltage is to be formed is prepared. In the step (b), a first insulating film, a first conductive film and a second insulating film are formed in this order on an upper surface of the semiconductor substrate in the memory cell array region. In the step (c), a third insulating film is formed on the upper surface of the semiconductor substrate in the high-voltage system peripheral circuit region. In the step (d), a fourth insulating film is formed on the upper surface of the semiconductor substrate in the low-voltage system peripheral circuit region. In the step (e), a second conductive film and a fifth insulating film are formed in this order on the entirety of upper surfaces of the second to fourth insulating films. In the step (f), the second conductive film and the fifth insulating film in the high-voltage system peripheral circuit region are partially removed. The portion of the second conductive film that is not removed in the step (f) in the high-voltage system peripheral circuit region becomes a gate electrode of the second transistor. In the step (g), a first thermal oxide film having a first bird's beak is formed in a side surface of the gate electrode. In the step (h), the first and second conductive films as well as the second and fifth insulating films in the memory cell array region are partially removed. The portion of the first conductive film that is not removed in the step (h) in the memory cell array region becomes a floating gate of the first transistor, and the portion of the second conductive film that is not removed in the step (h) in the memory cell array region becomes a control gate of the first transistor. In the step (i), the second conductive film and the fifth insulating film in the low-voltage system peripheral circuit region are partially removed. The portion of the second conductive film that is not removed in the step (i) in the low-voltage system peripheral circuit region becomes a gate electrode of the third transistor. In the step (j), a second thermal oxide film having a second bird's beak which is smaller than the first bird's beak is formed in a side surface of the floating gate. In the step (k), a third thermal oxide film having a third bird's beak which is smaller than the first bird's beak is formed in a side surface of the gate electrode of the third transistor.

All of deterioration in transistor characteristics of the first transistor formed in the memory cell array region, deterioration in transistor characteristics of the third transistor formed in the low-voltage system peripheral circuit region, and concentration of the electrical field at the gate edges of the second transistor formed in the high-voltage system peripheral circuit region can be avoided.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view showing the structure of a memory cell transistor according to a first embodiment of the present invention;

FIGS. 2 to 11 are cross-sectional views showing a manufacturing method of the memory cell transistor according to the first embodiment of the present invention in order of steps;

FIG. 12 is a cross-sectional view showing the structure of a transistor for a peripheral circuit according to the first embodiment of the present invention;

FIGS. 13 to 21 are cross-sectional views showing a manufacturing method of the transistor for the peripheral circuit according to the first embodiment of the present invention in order of steps;

FIG. 22 is a cross-sectional view showing the structure of a memory cell transistor according to a second embodiment of the present invention;

FIGS. 23 to 29 are cross-sectional views showing a manufacturing method of the memory cell transistor according to the second embodiment of the present invention in order of steps;

FIG. 30 is a cross-sectional view showing the structure of a transistor for a peripheral circuit according to the second embodiment of the present invention;

FIGS. 31 to 36 are cross-sectional views showing a manufacturing method of the transistor for the peripheral circuit according to the second embodiment of the present invention in order of steps;

FIG. 37 is a cross-sectional view showing the structure of a semiconductor device according to a third embodiment of the present invention;

FIG. 38 is a top view showing the structure of a memory cell array region in the structure of the semiconductor device according to the third embodiment; and

FIGS. 39 to 49 are cross-sectional views showing a manufacturing method of the semiconductor device according to the third embodiment of the present invention in order of steps.

### DESCRIPTION OF THE PREFERRED EMBODIMENTS

### First Embodiment

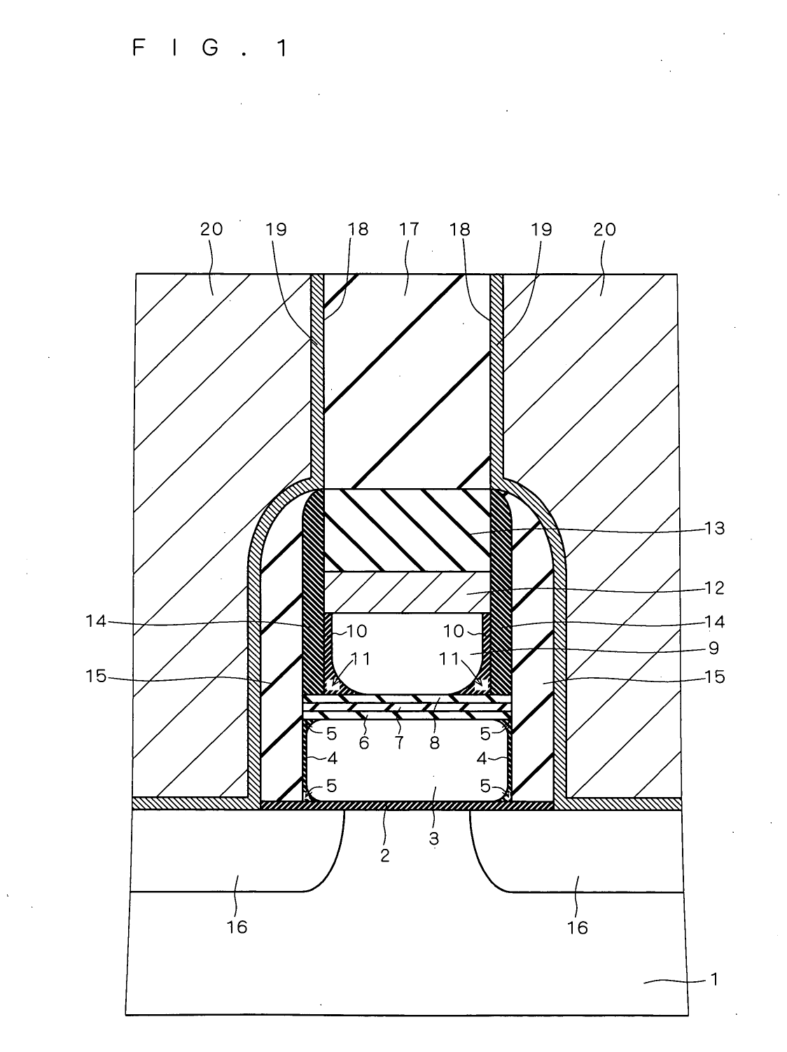

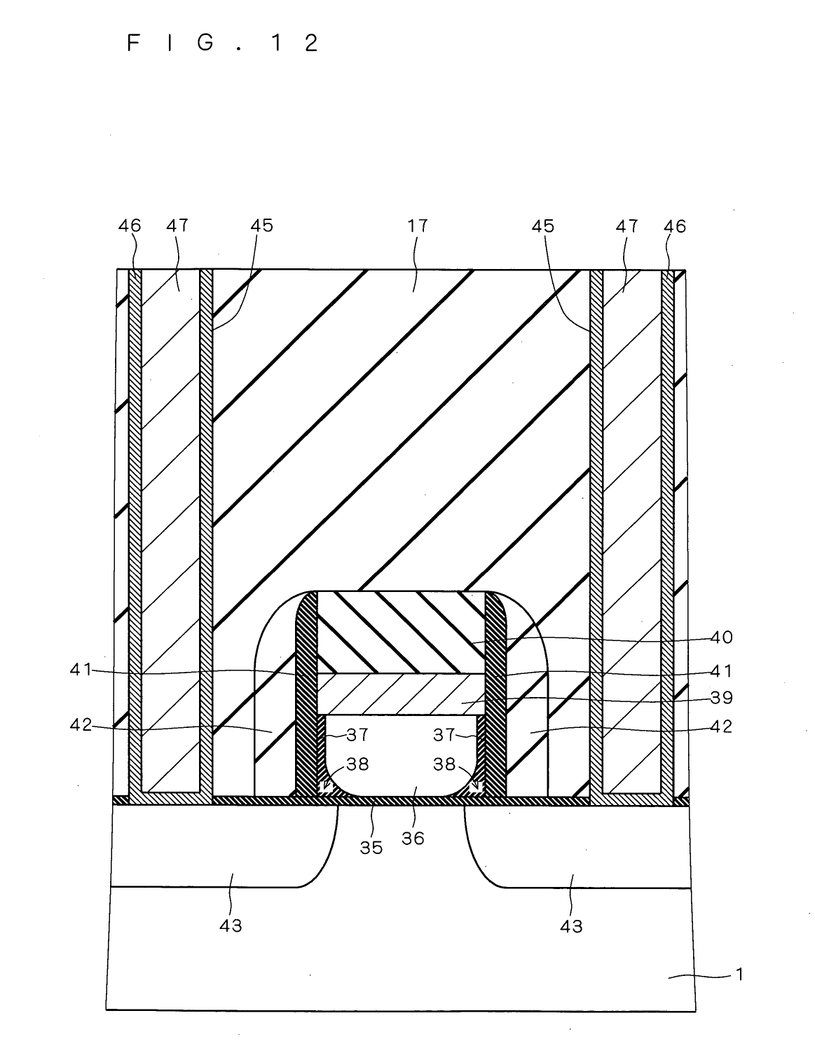

FIG. 1 is a cross-sectional view showing the structure of a memory cell transistor according to a first embodiment of the present invention, and FIG. 12 is a cross-sectional view showing the structure of a transistor for a peripheral circuit according to the first embodiment. The memory cell transistor shown in FIG. 1 is formed in a memory cell array region of a silicon substrate 1, and the transistor for the peripheral circuit shown in FIG. 12 is formed in a peripheral circuit region of the same silicon substrate 1.

With reference to FIG. 1, a tunnel oxide film 2 is formed on the upper surface of the silicon substrate 1. A floating gate 3 is formed on the upper surface of the tunnel oxide film 2. Thermal oxide films 4 are formed in the side surfaces of the floating gate 3. A silicon oxide film 6, a silicon nitride film 7 and a silicon oxide film 8 are formed in this order on the upper surface of the floating gate 3. An insulating film having a three-layer structure where the silicon nitride film 7 is sandwiched between the silicon oxide films 6 and 8 is referred to as “ONO film”.

A control gate is formed partially on the upper surface of the silicon oxide film 8. The control gate has a polysilicon film 9 that is formed partially on the upper surface of the silicon oxide film 8, and a tungsten film 12 that is formed on the upper surface of the polysilicon film 9. The dimension of the control gate in a gate length direction (in a lateral direction in the figure) is smaller than that of the floating gate 3 in the gate length direction. Thermal oxide films 10 are formed in the side surfaces of the polysilicon film 9. A silicon nitride film 13 is formed on the upper surface of the tungsten film 12.

Bird's beaks 5 are respectively formed in the thermal oxide films 4 at the bottom surface ends of the floating gate 3, which are defined by the upper surface of the tunnel oxide film 2 and the side surfaces of the floating gate 3, and at the upper surface ends of the floating gate 3, which are defined by the bottom surface of the silicon oxide film 6 and the side surfaces of the floating gate 3. In addition, bird's beaks 11 are formed in thermal oxide films 10 at the bottom surface ends of the control gate, which are defined by the upper surface of the silicon oxide film 8 and the side surfaces of the polysilicon film 9. The dimensions of the thermal oxide films 4 in the gate length direction are smaller than those of the thermal oxide films 10 in the gate length direction. In addition, the bird's beaks 5 are smaller than the bird's beaks 11.

Sidewall insulating films 14 are formed on the upper surface of the silicon oxide film 8 and on the respective side surfaces of the control gate and the silicon nitride film 13. Sidewall insulating films 15 are formed on the upper surface of the tunnel oxide film 2 and on the respective side surfaces of the floating gate 3, the ONO film and the sidewall insulating films 14.

Source and drain regions 16 are formed in the upper surface portion of the silicon substrate 1 in such a manner as to face each other with a channel formation region that is formed beneath the floating gate 3 in between.

An interlayer insulating film 17 is formed so as to cover the memory cell transistor, and contact holes 18 are formed in the interlayer insulating film 17 so as to reach the upper surface of the source and drain regions 16. The inside of the contact holes 18 is filled in with a barrier metal film 19 and a tungsten film 20.

With reference to FIG. 12, a gate insulating film 35 is formed on the upper surface of the silicon substrate 1. A gate electrode is formed on the upper surface of the gate insulating film 35. The gate electrode has a polysilicon film 36 that is formed on the upper surface of the gate insulating film 35, and a tungsten film 39 that is formed on the upper surface of the polysilicon film 36. Thermal oxide films 37 are formed in the side surfaces of the polysilicon film 36. A silicon nitride film 40 is formed on the upper surface of the tungsten film 39.

Bird's beaks 38 are formed in the thermal oxide films 37 at the bottom surface ends of the gate electrode, which are defined by the upper surface of the gate insulating film 35 and the side surfaces of the polysilicon film 36. With reference to FIGS. 1 and 12, the dimensions of the thermal oxide films 4 in the gate length direction are smaller than those of the thermal oxide films 37 in the gate length direction. In addition, the bird's beaks 5 are smaller than the bird's beaks 38.

Sidewall insulating films 41 are formed on the upper surface of the gate insulating film 35 and on the respective side surfaces of the gate electrode and the silicon nitride film 40. Sidewall insulating films 42 are formed on the upper surface of the gate insulating film 35 and on the side surfaces of the sidewall insulating films 41.

Source and drain regions 43 are formed in the upper surface portion of the silicon substrate 1 in such a manner as to face each other with a channel formation region that is formed beneath the gate electrode in between.

An interlayer insulating film 17 is formed so as to cover the transistor for the peripheral circuit, and contact holes 45 are formed in the interlayer insulating film 17 so as to reach the upper surface of the source and drain regions 43. The inside of the contact holes 45 is filled in with a barrier metal film 46 and a tungsten film 47.

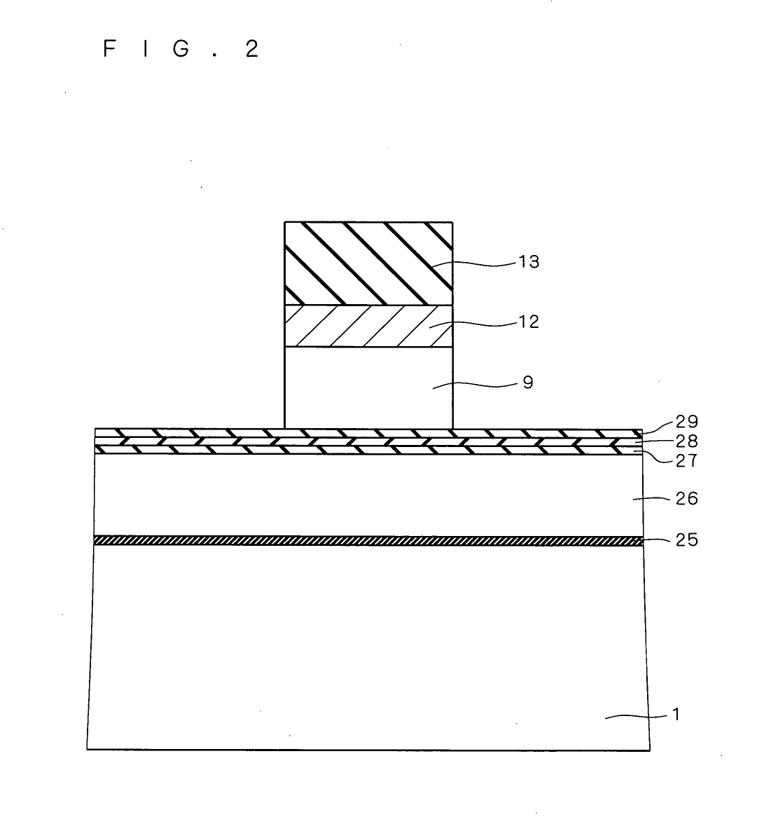

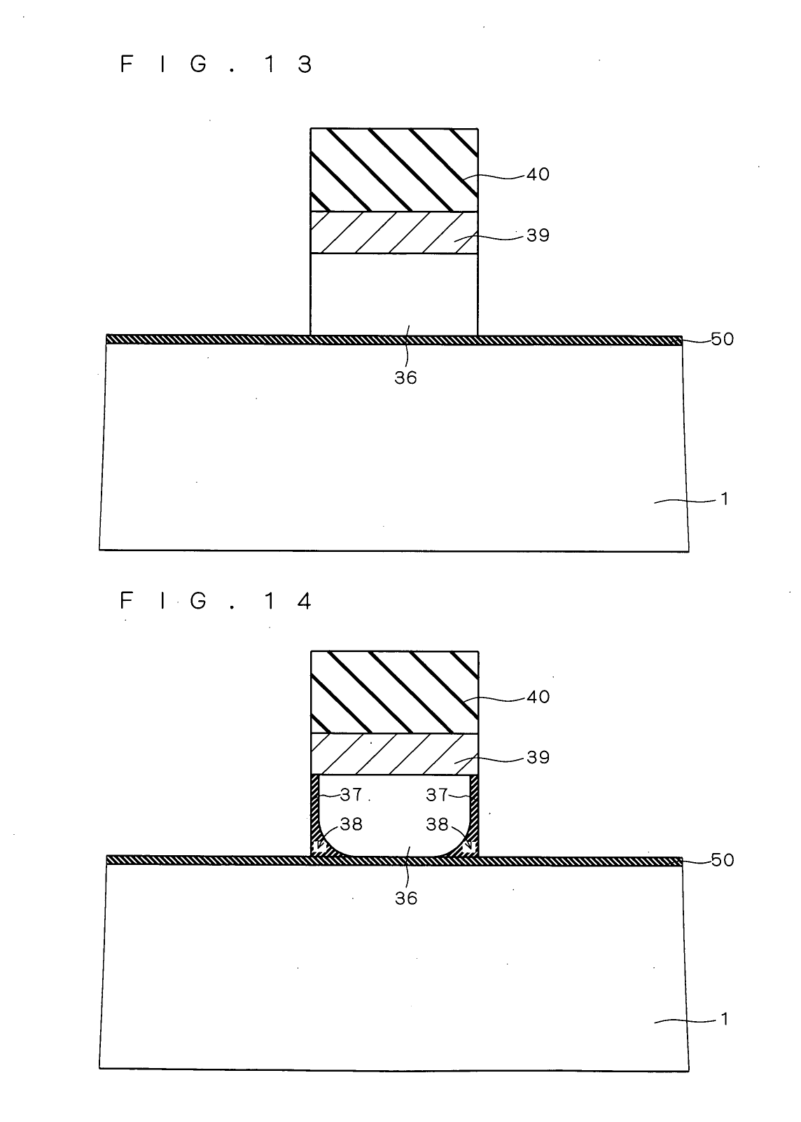

In the following, manufacturing methods will be described. FIGS. 2 to 11 are cross-sectional views showing a manufacturing method of the memory cell transistor according to the first embodiment in order of steps. FIGS. 13 to 21 are cross-sectional views showing a manufacturing method of the transistor for the peripheral circuit according to the first embodiment in order of steps.

With reference to FIGS. 2 and 13, a silicon oxide film 25 having a thickness of approximately 8 to 12 nm, a polysilicon film 26 having a thickness of approximately 50 to 150 nm, a silicon oxide film 27 having a thickness of approximately 2 to 4 nm, a silicon nitride film 28 having a thickness of approximately 5 to 15 nm, and a silicon oxide film 29 having a thickness of approximately 5 to 15 nm are formed in this order on the upper surface of a silicon substrate 1 in a memory cell array region. In addition, a silicon oxide film 50 having a thickness of approximately 20 to 200 nm is formed on the upper surface of the silicon substrate 1 in a peripheral circuit region.

Next, a polysilicon film having a thickness of approximately 50 to 150 nm, a tungsten film having a thickness of approximately 20 to 60 nm, and a silicon nitride film having a thickness of approximately 200 to 300 nm are formed in this order on the entire surface, and after that, these films are patterned in accordance with a photolithographic method and an anisotropic etching method. Thus, a first layered structure including the polysilicon film 9, the tungsten film 12 and the silicon nitride film 13 is formed on the upper surface of the silicon oxide film 29 in the memory cell array region, while a second layered structure including the polysilicon film 36, the tungsten film 39 and the silicon nitride film 40 is formed on the silicon oxide film 50 in the peripheral circuit region.

The gate structure of the memory cell transistor is defined by the first layered structure, while the gate structure of the transistor for the peripheral circuit is defined by the second layered structure. Therefore, with the manufacturing method of the semiconductor device according to the first embodiment, both the gate structure of the memory cell transistor and the gate structure of the transistor for the peripheral circuit can be defined as a result of one photolithographic step. Thus, reduction in cost can be achieved in comparison with a manufacturing process where a photolithographic step of defining the gate structure of a memory cell transistor and a photolithographic step of defining the gate structure of a transistor for a peripheral circuit are carried out as separate steps (see, for example, FIG. 2 of Japanese Patent Application Laid-Open No. 2003-68889).

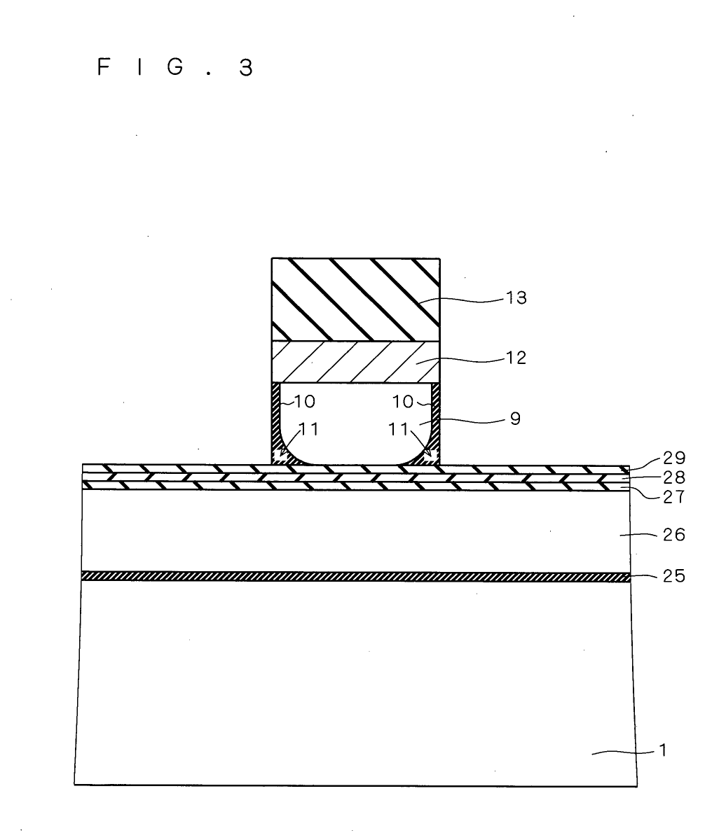

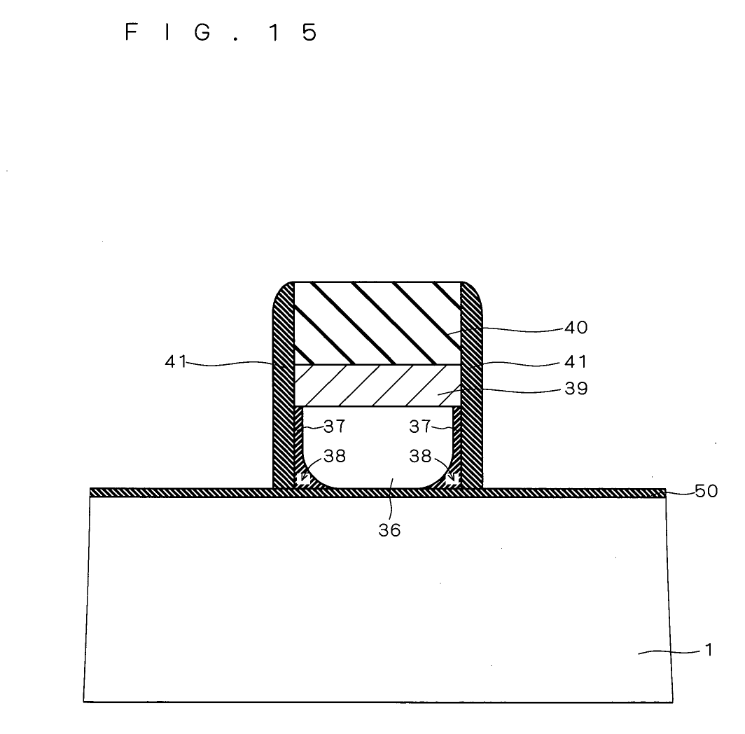

Next, with reference to FIGS. 3 and 14, thermal oxidation is carried out under process conditions (1000° C., growth amount of thermal oxide film: approximately 13 to 15 nm) which are optimal for the transistor for the peripheral circuit. Here, in the case of a polymetal gate device as in the first embodiment, it is desirable to use selective oxidation conditions (approximately 800 to 900° C.), in order to avoid oxidation of the tungsten films 12 and 39. Thus, thermal oxide films 10 are formed in the side surfaces of the polysilicon film 9 in the memory cell array region and, also, thermal oxide films 37 are formed in the side surfaces of the polysilicon film 36 in the peripheral circuit region. The thermal oxide films 10 and 37 have bird's beaks 11 and 38, respectively. The length of the bird's beaks is, for example, approximately 25 to 30 nm.

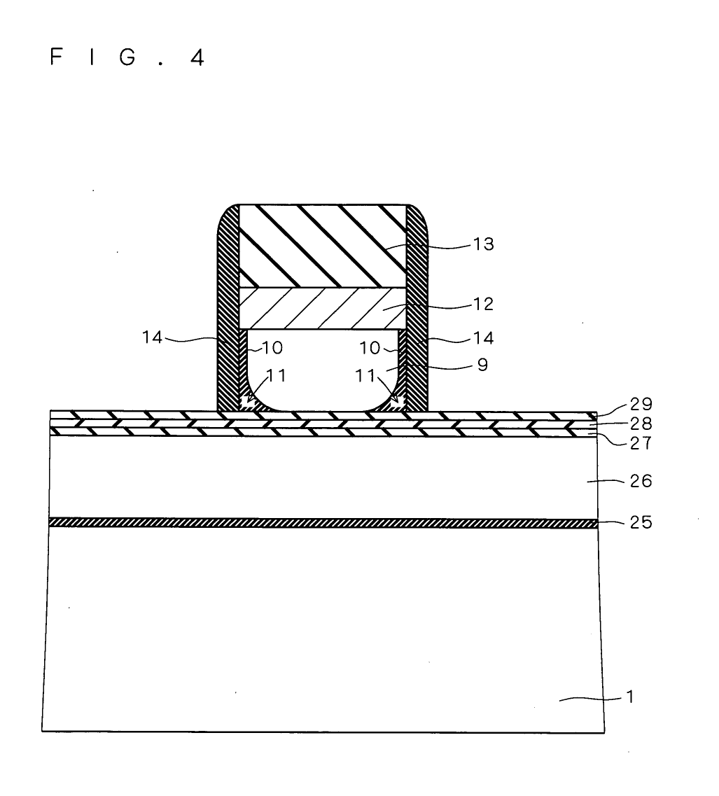

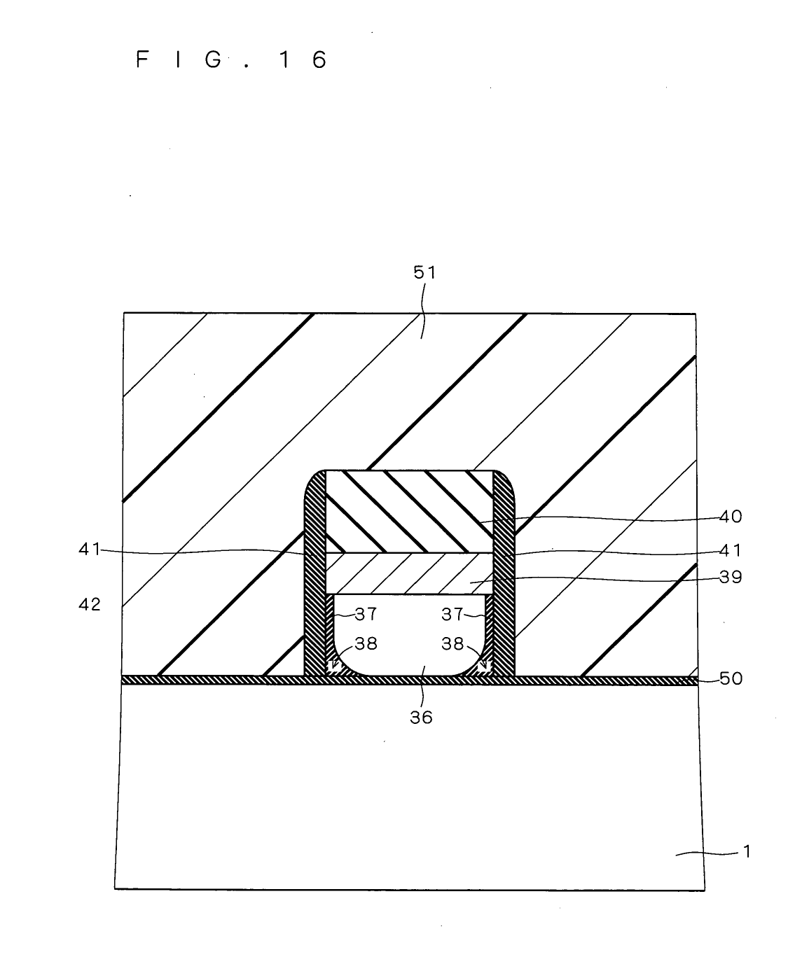

Next, with reference to FIGS. 4 and 15, an insulating film which has a thickness of approximately 10 to 30 nm and is made of a material having an oxygen blocking property (for example, silicon nitride film) is formed on the entire surface in accordance with a CVD method, and after that, etch-back is carried out. Thus, sidewall insulating films 14 are formed in the memory cell array region, and sidewall insulating films 41 are formed in the peripheral circuit region.

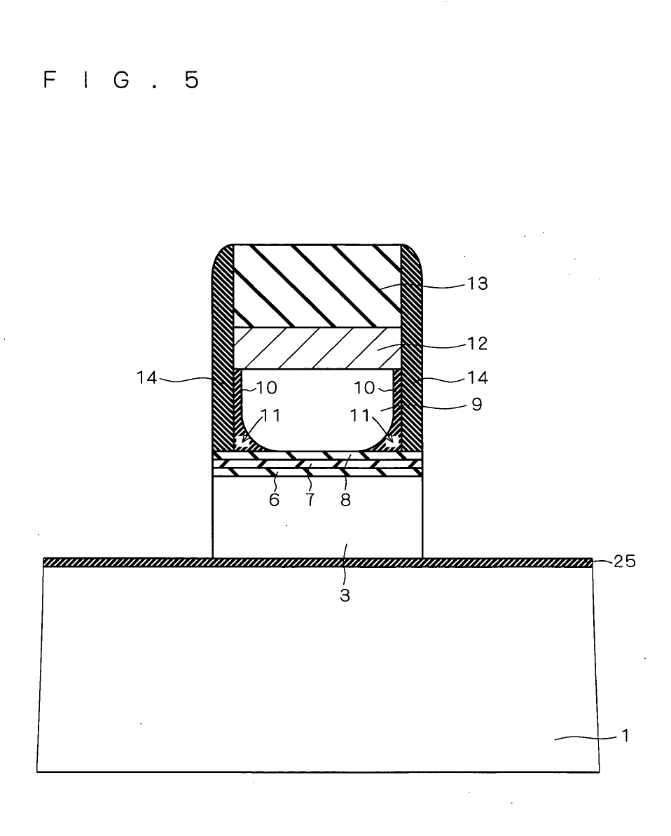

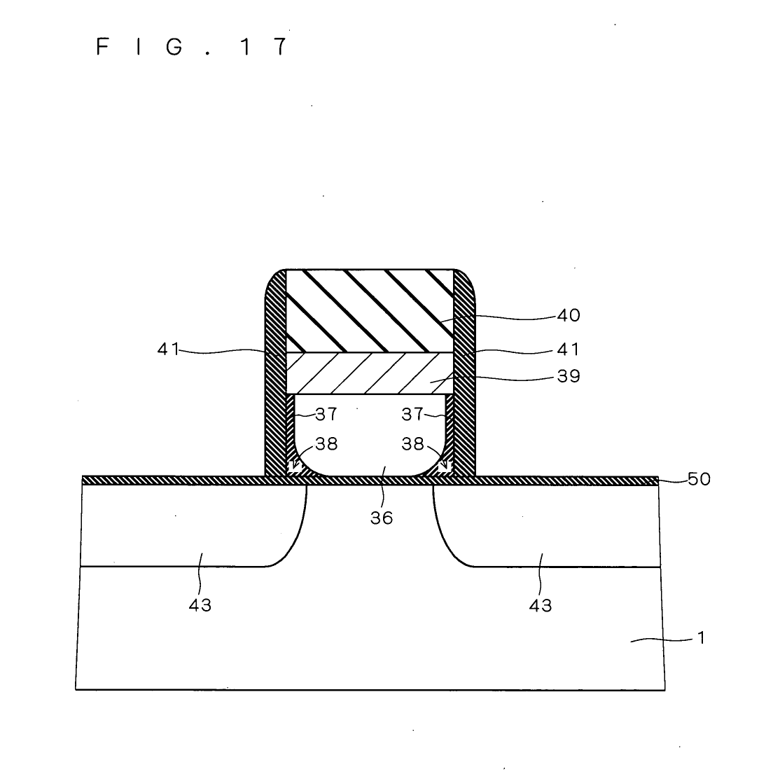

Next, with reference to FIGS. 5 and 16, a photoresist 51 which covers the peripheral circuit region is formed in accordance with a photolithographic method. Next, the photoresist 51, the silicon nitride film 13 and the sidewall insulating film 14 are used as etching masks, and the silicon oxide film 29, the silicon nitride film 28, the silicon oxide film 27 and the polysilicon film 26 are etched in this order in accordance with an anisotropic etching method. Thus, the portions of the silicon oxide film 29, the silicon nitride film 28, the silicon oxide film 27 and the polysilicon film 26 which are not etched become the silicon oxide film 8, the silicon nitride film 7, the silicon oxide film 6 and the floating gate 3, respectively. After that, the photoresist 51 is removed.

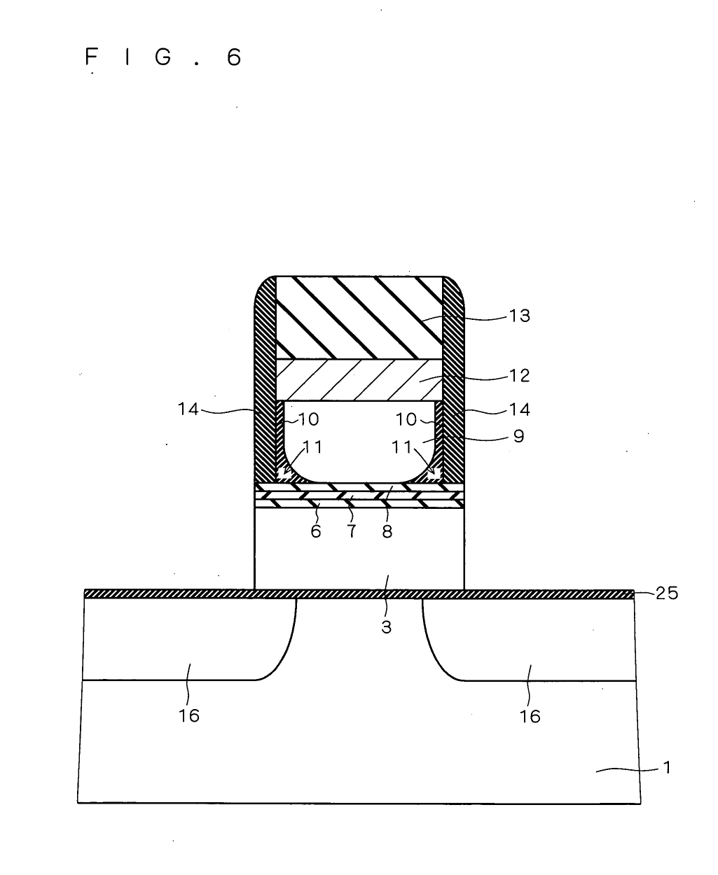

Next, with reference to FIGS. 6 and 17, impurities are introduced in the upper surface portion of the silicon substrate 1, through the silicon oxide films 25 and 50, in accordance with an ion implantation method. Thus, source and drain regions 16 are formed in the upper surface portion of the silicon substrate 1 in the memory cell array region and, also, source and drain regions 43 are formed in the upper surface portion of the silicon substrate 1 in the peripheral circuit region.

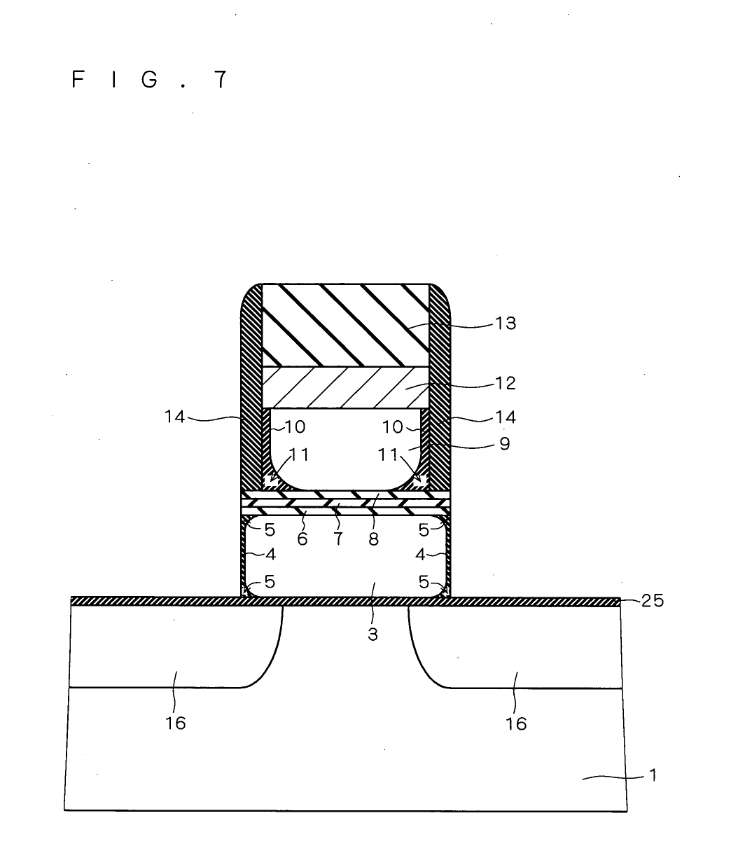

Next, with reference to FIG. 7, thermal oxidation is carried out under process conditions (1000° C., growth amount of thermal oxide film: 8 to 10 nm) which are optimal for the memory cell transistor. Thus, thermal oxide films 4 are formed in the side surfaces of the floating gate 3 in the memory cell array region. The thermal oxide films 4 have bird's beaks 5. The length of the bird's beaks is, for example, approximately 15 to 20 nm. At this time, sidewall insulating films 41 are formed on the side surfaces of the polysilicon film 36 in the peripheral circuit region, as shown in FIG. 17, and the sidewall insulating films 41 are made of a material having an oxygen blocking property. Therefore, the polysilicon film 36 is not oxidized through the thermal oxidation for the formation of the thermal oxide films 4, so that it is possible to avoid a state where the thickness and the size of the bird's beaks 38 in the thermal oxide films 37 that are already formed fluctuate. In the same manner, the sidewall insulating films 14 are formed on the side surfaces of the polysilicon film 9 in the memory cell array region. Therefore, the polysilicon film 9 is not oxidized through the thermal oxidation for the formation of the thermal oxide films 4, so that it is possible to avoid a state where the thickness and the size of the bird's beaks 11 in the thermal oxide films 10 that are already formed fluctuate.

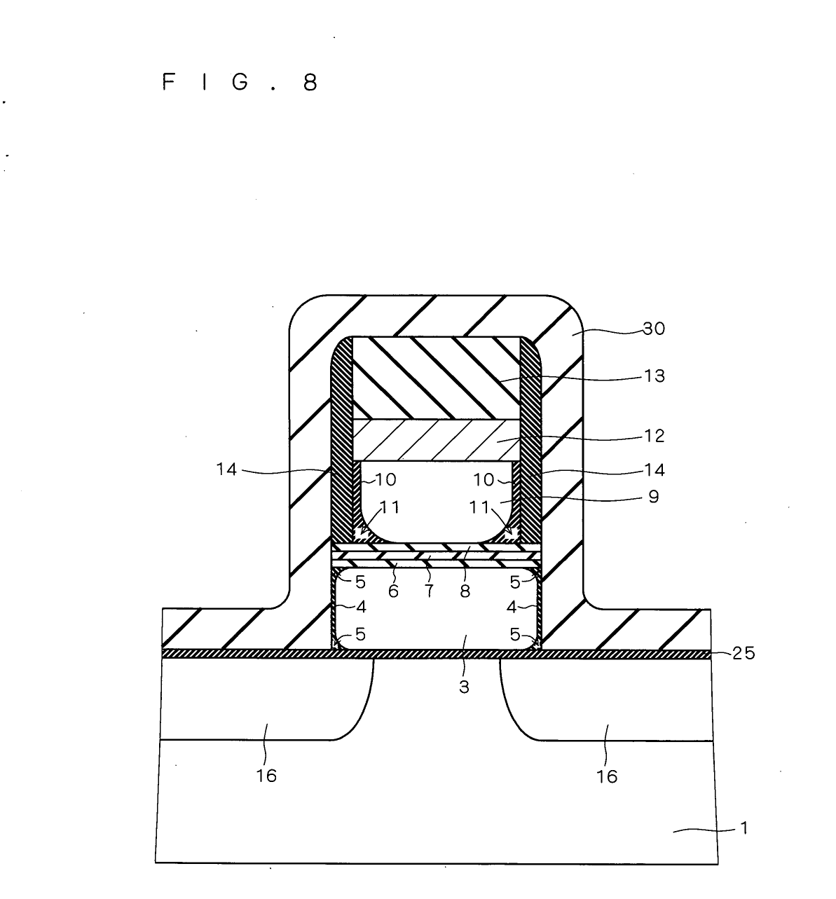

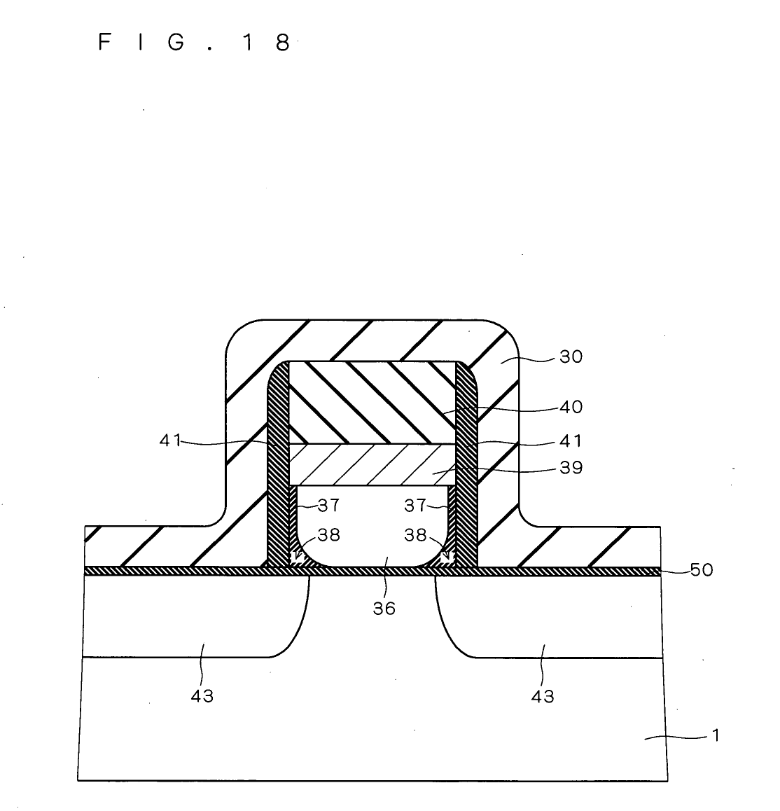

Next, with reference to FIGS. 8 and 18, a silicon nitride film 30 having a thickness of approximately 600 to 800 nm is formed on the entire surface in accordance with a CVD method.

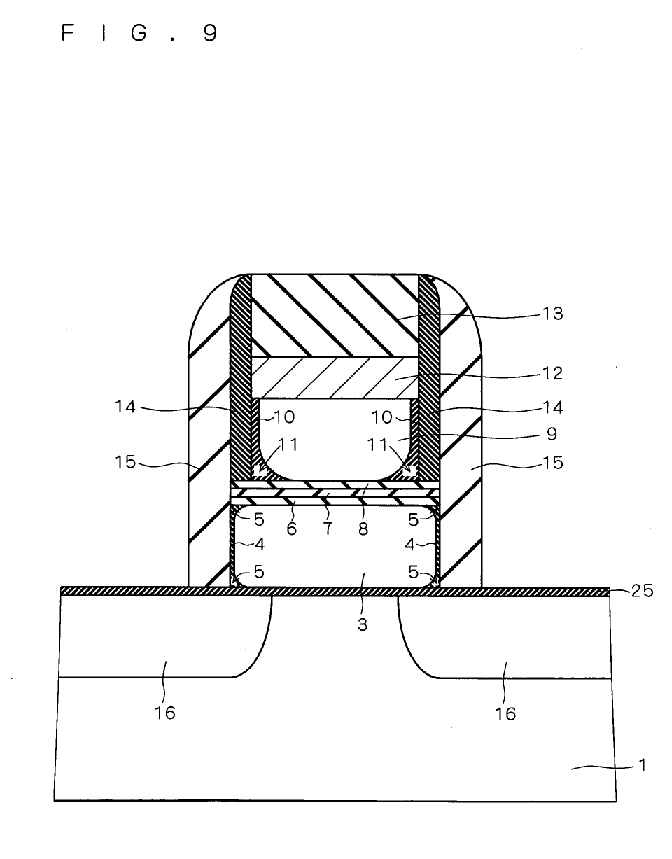

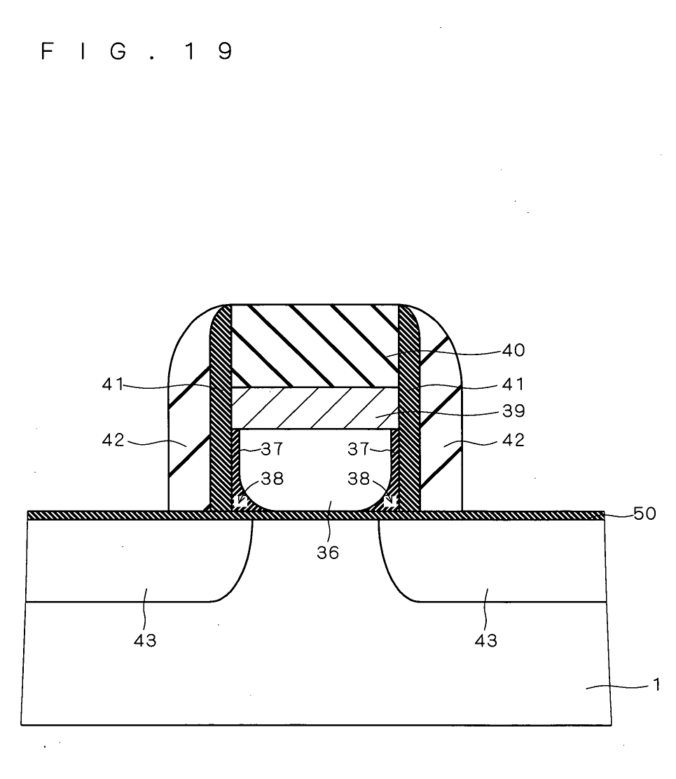

Next, with reference to FIGS. 9 and 19, the silicon nitride film 30 is etched back, so that sidewall insulating films 15 are formed in the memory cell array regions and, also, sidewall insulating films 42 are formed in the peripheral circuit region.

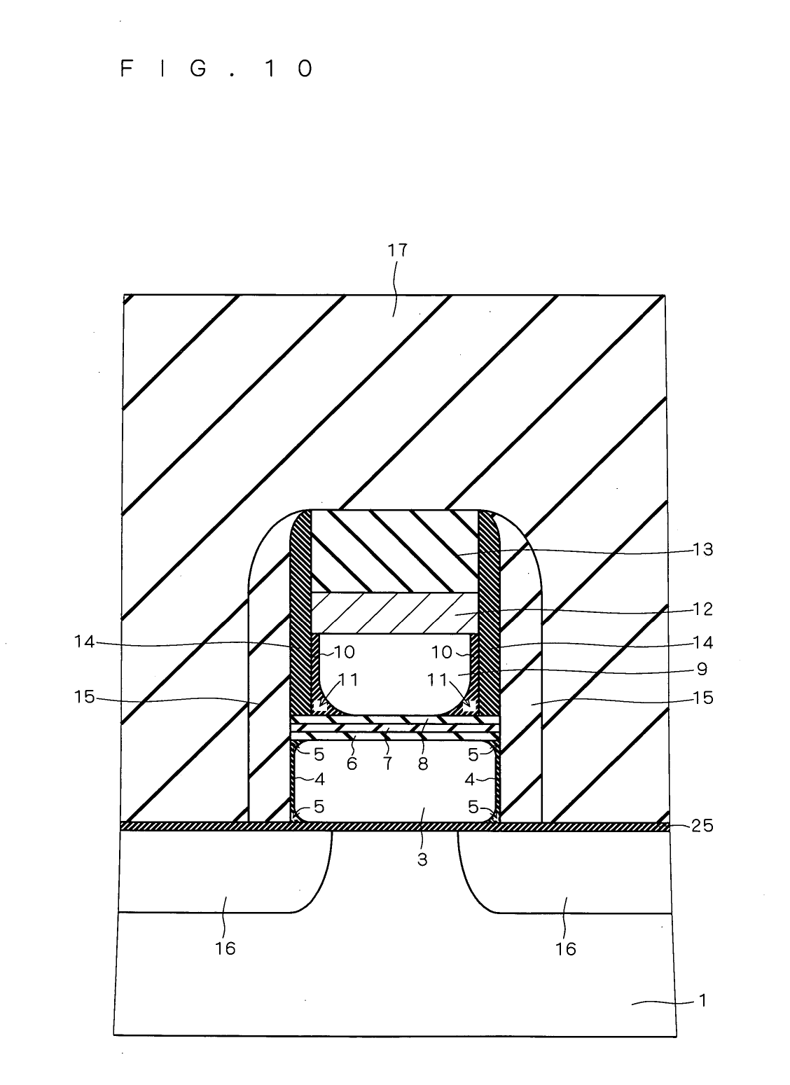

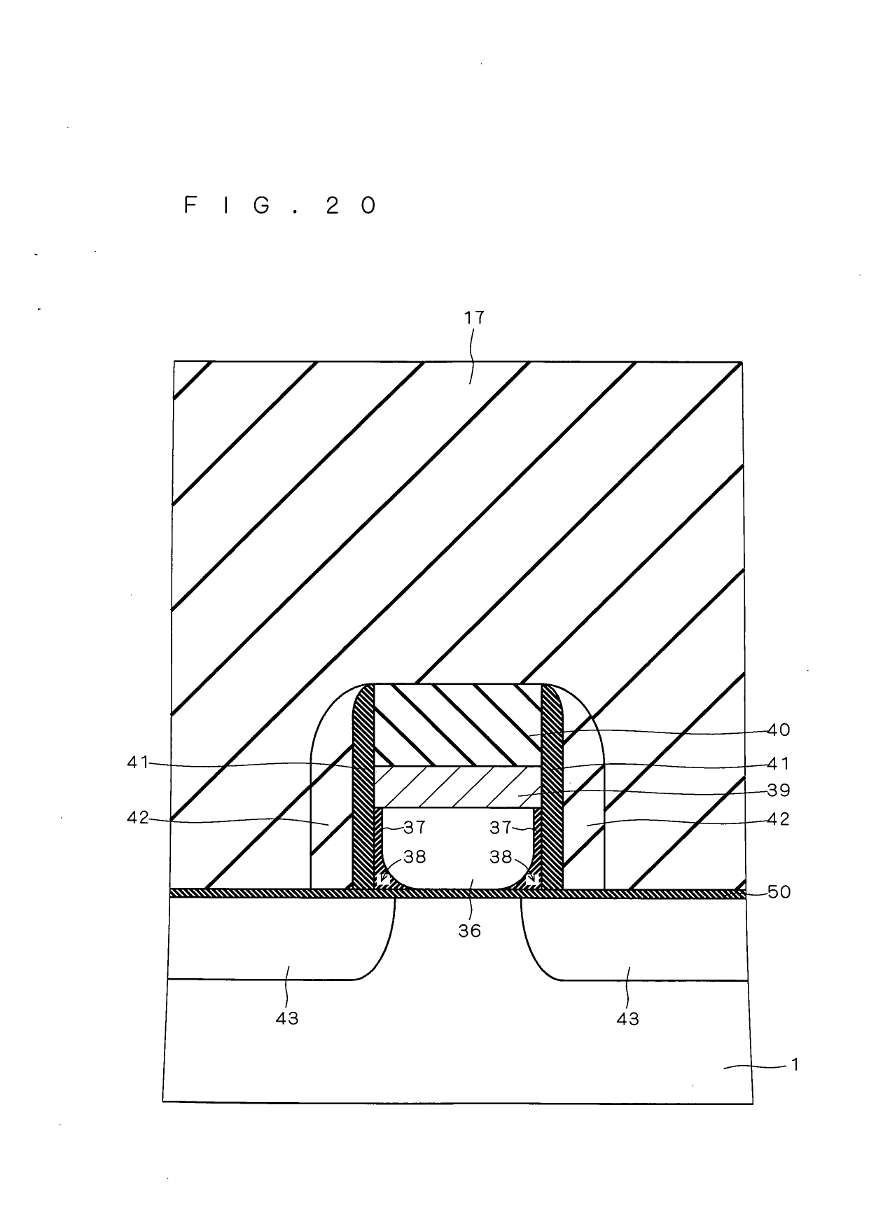

Next, with reference to FIGS. 10 and 20, an interlayer insulating film 17 which is made of BPTEOS or the like and has a thickness of approximately 500 to 1500 nm is formed on the entire surface in accordance with a CVD method.

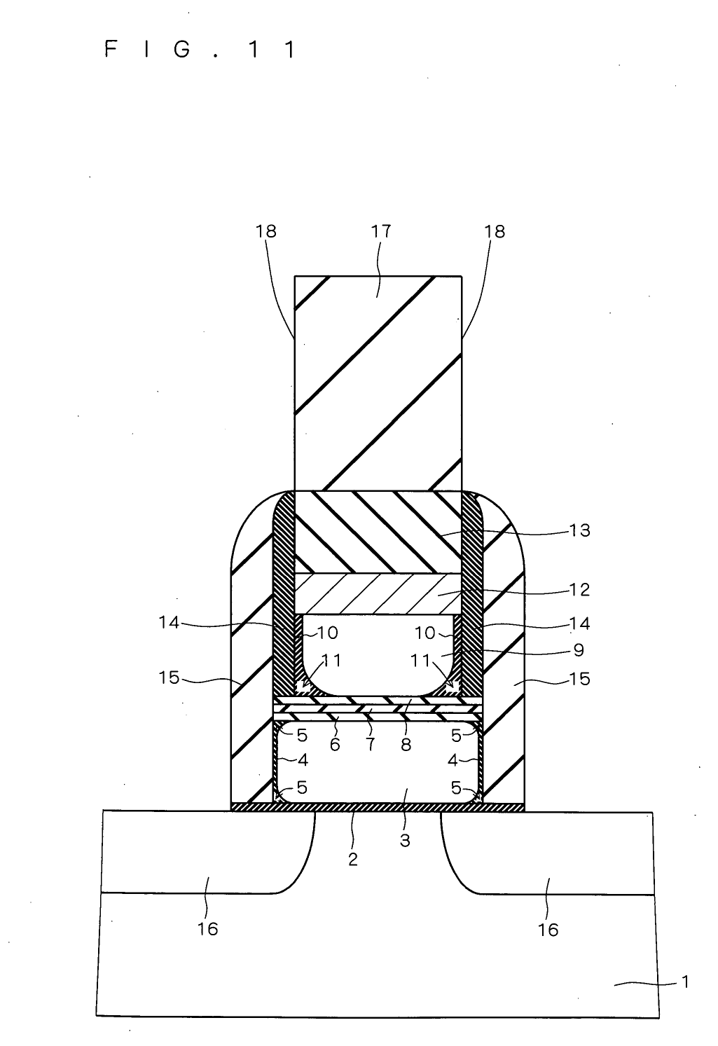

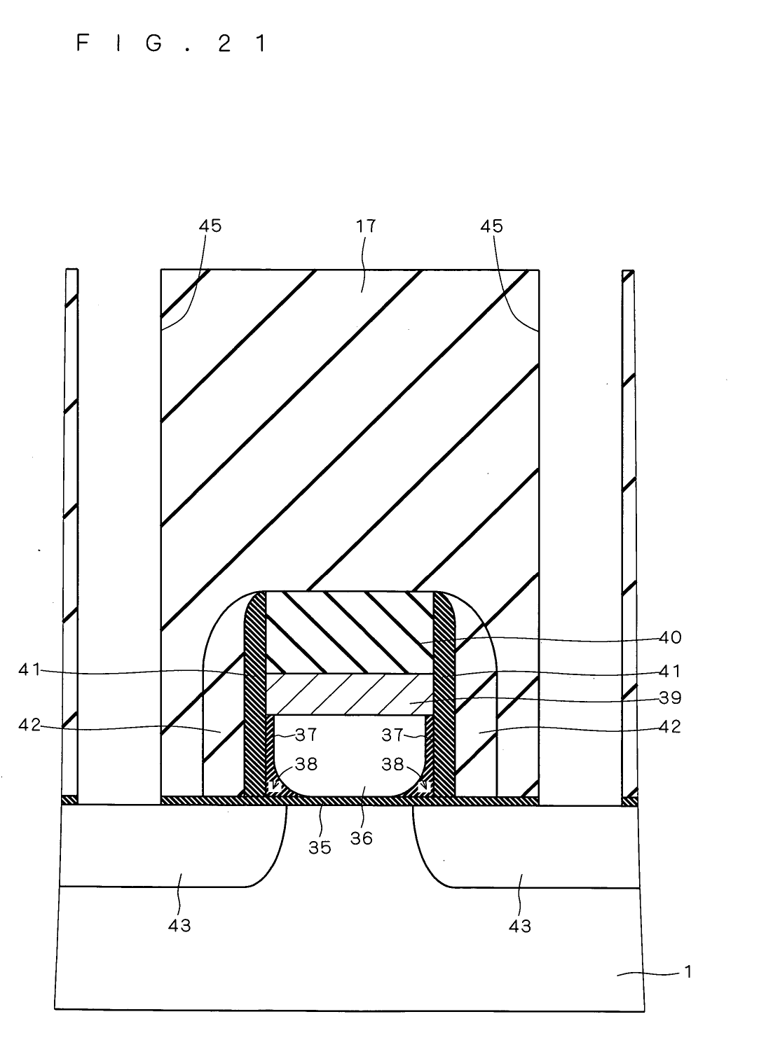

Next, with reference to FIGS. 11 and 21, contact holes 18 are formed in the interlayer insulating film 17 in the memory cell array region in a self-aligned manner in accordance with a photolithographic method and an anisotropic etching method and, also, contact holes 45 are formed in the interlayer insulating film 17 in the peripheral circuit region. The silicon oxide film 25 in the portion which is sandwiched between the floating gate 3 and the silicon substrate 1 functions as the tunnel oxide film 2, while the silicon oxide film 50 in the portion which is sandwiched between the polysilicon film 36 and the silicon substrate 1 functions as the gate insulating film 35.

Next, barrier metal films 19 and 46 which are made of titanium nitride or the like and have a thickness of approximately 10 to 20 nm are formed in accordance with a CVD method, and after that, tungsten films 20 and 47 are formed on the barrier metal films 19 and 46 so that the inside of the contact holes 18 and 45 is filled in; thus, the structures shown in FIGS. 1 and 12 are obtained.

With the manufacturing method of the semiconductor device according to the first embodiment, the step of forming the thermal oxide films 4 in the side surfaces of the floating gate 3 of a memory cell transistor (FIG. 7) and the step of forming the thermal oxide films 37 in the side surfaces of the gate electrode (polysilicon film 36) of the transistor for the peripheral circuit (FIG. 14) are carried out as separate steps. Consequently, the bird's beaks 5 in the thermal oxide films 4 can be made smaller than the bird's beaks 38 in the thermal oxide films 37. As a result, with the semiconductor device according to the first embodiment, deterioration in the transistor characteristics, e.g., the lead current is reduced, can be avoided in the memory cell transistor, and concentration of the electrical field at the gate edges can be avoided in the transistor for a peripheral circuit.

### Second Embodiment

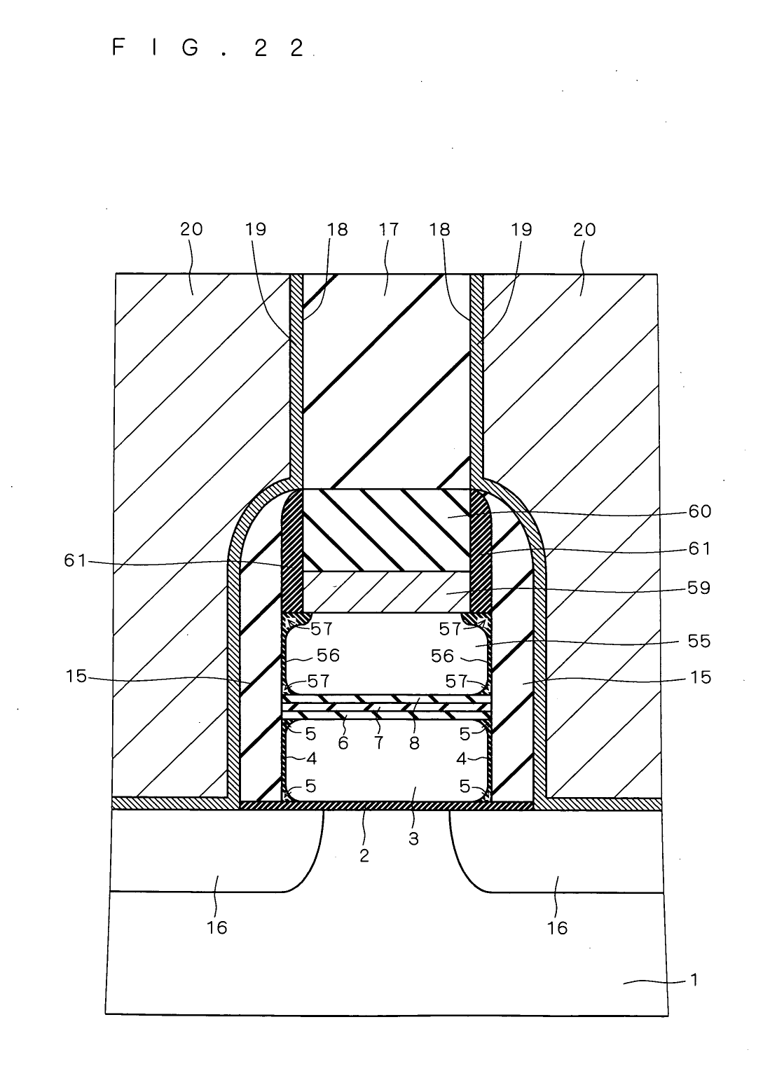

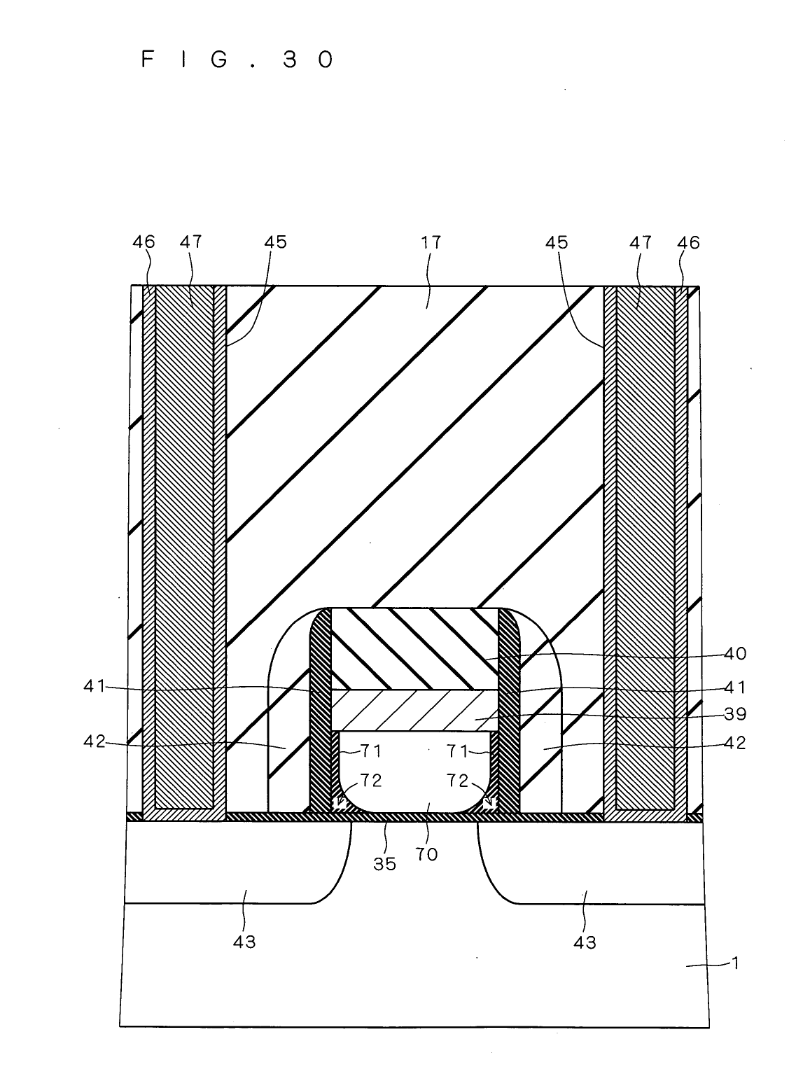

FIG. 22 is a cross-sectional view showing the structure of a memory cell transistor according to a second embodiment of the present invention, and FIG. 30 is a cross-sectional view showing the structure of a transistor for a peripheral circuit according to the second embodiment. The memory cell transistor shown in FIG. 22 is formed in a memory cell array region of a silicon substrate 1, and the transistor for the peripheral circuit shown in FIG. 30 is formed in the peripheral circuit region of the same silicon substrate 1.

With reference to FIG. 22, a tunnel oxide film 2 is formed on the upper surface of the silicon substrate 1. A floating gate 3 is formed on the upper surface of the tunnel oxide film 2. Thermal oxide films 4 are formed in the side surfaces of the floating gate 3. An ONO film where a silicon oxide film 6, a silicon nitride film 7 and a silicon oxide film 8 are layered in this order is formed on the upper surface the floating gate 3.

A control gate is formed on the upper surface of the silicon oxide film 8. The control gate has a polysilicon film 55 that is formed on the upper surface of the silicon oxide film 8, and a tungsten film 59 that is formed partially on the upper surface of the polysilicon film 55. The dimension of the polysilicon film 55 in a gate length direction is equal to that of the floating gate 3 in the gate length direction. Thermal oxide films 56 are formed in the side surfaces of the polysilicon film 55. A silicon nitride film 60 is formed on the upper surface of tungsten film 59. The respective dimensions of the tungsten film 59 and the silicon nitride film 60 in the gate length direction are smaller than those of the floating gate 3 and the polysilicon film 55 in the gate length direction.

Bird's beaks 5 are formed in the thermal oxide films 4 at the bottom surface ends and the upper surface ends of the floating gate 3, respectively. In addition, bird's beaks 57 are formed in the thermal oxide films 56 at the bottom surface ends of the polysilicon film 55, which are defined by the upper surface of the silicon oxide film 8 and the side surfaces of the polysilicon film 55, and at the upper surface ends of the polysilicon film 55, which are defined by the upper surface and the side surfaces of polysilicon film 55, respectively. The dimension of the thermal oxide films 56 in the gate length direction is equal to that of the thermal oxide films 4 in the gate length direction. The size of the bird's beaks 57 which are formed at the bottom surface ends of the polysilicon film 55 is equal to that of the bird's beaks 5 in the thermal oxide films 4. Meanwhile, the size of the bird's beaks 57 which are formed at the upper surface ends of the polysilicon film 55 is greater than that of the bird's beaks 5 in the thermal oxide films 4.

Sidewall insulating films 61 are formed on the upper surface of the polysilicon film 55 and on the respective side surfaces of the tungsten film 59 and the silicon nitride film 60. Sidewall insulating films 15 are formed on the upper surface of the tunnel oxide film 2 and on the respective side surfaces of the floating gate 3, the ONO film, the polysilicon film 55 and the sidewall insulating films 61.

Source and drain regions 16 are formed in the upper surface portion of the silicon substrate 1 in such a manner as to face each other with a channel formation region that is formed beneath the floating gate 3 in between.

An interlayer insulating film 17 is formed so as to cover the memory cell transistor, and contact holes 18 are formed in the interlayer insulating film 17 so as to reach the upper surface of the source and drain regions 16. The inside of the contact holes 18 is filled in with a barrier metal film 19 and a tungsten film 20.

With reference to FIG. 30, a gate insulating film 35 is formed on the upper surface of the silicon substrate 1. A gate electrode is formed on the upper surface of the gate insulating film 35. The gate electrode has a polysilicon film 70 that is formed on the upper surface of the gate insulating film 35, and a tungsten film 39 that is formed on the upper surface of the polysilicon film 70. Thermal oxide films 71 are formed in the side surfaces of the polysilicon film 70. A silicon nitride film 40 is formed on the upper surface of the tungsten film 39.

Bird's beaks 72 are formed in the thermal oxide films 71 at the bottom surface ends of the gate electrode, which are defined by the upper surface of the gate insulating film 35 and the side surfaces of the polysilicon film 70. With reference to FIGS. 22 and 30, the dimensions of the thermal oxide films 4 and 56 in the gate length direction are smaller than that of the thermal oxide films 71 in the gate length direction. In addition, the bird's beaks 5 are smaller than the bird's beaks 72.

Sidewall insulating films 41 are formed on the upper surface of the gate insulating film 35 and on the respective side surfaces of the gate electrode and the silicon nitride film 40. Sidewall insulating films 42 are formed on the upper surface of the gate insulating film 35 and on the side surfaces of the sidewall insulating films 41.

Source and drain regions 43 are formed in the upper surface portion of the silicon substrate 1 in such a manner as to face each other with a channel formation region that is formed beneath the gate electrode in between.

An interlayer insulating film 17 is formed so as to cover the transistor for the peripheral circuit, and contact holes 45 are formed in the interlayer insulating film 17, so as to reach the upper surface of the source and the drain regions 43. The inside of the contact holes 45 is filled in with a barrier metal film 46 and a tungsten film 47.

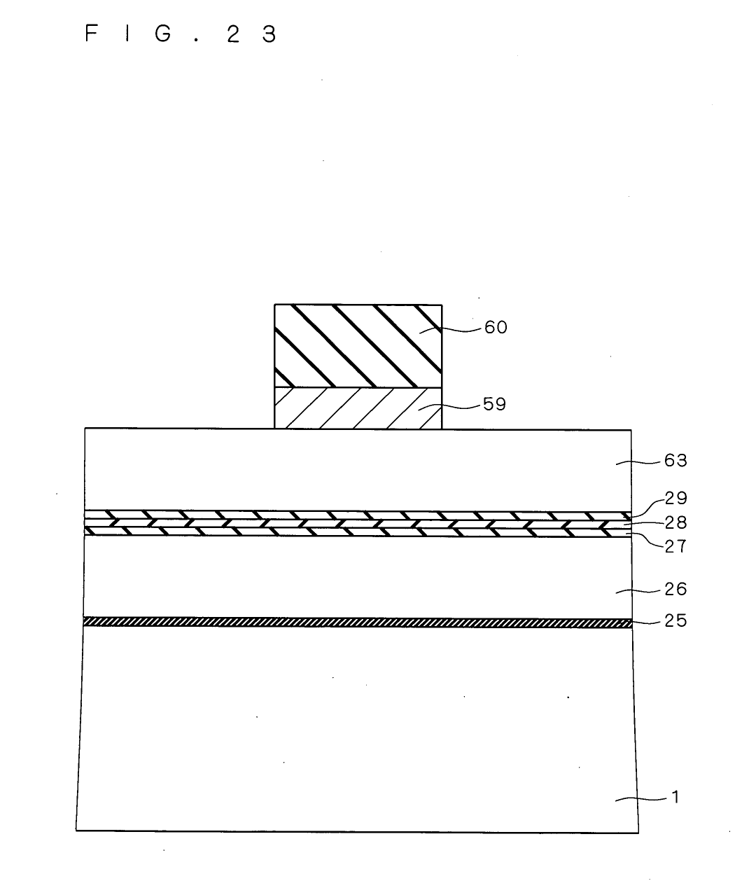

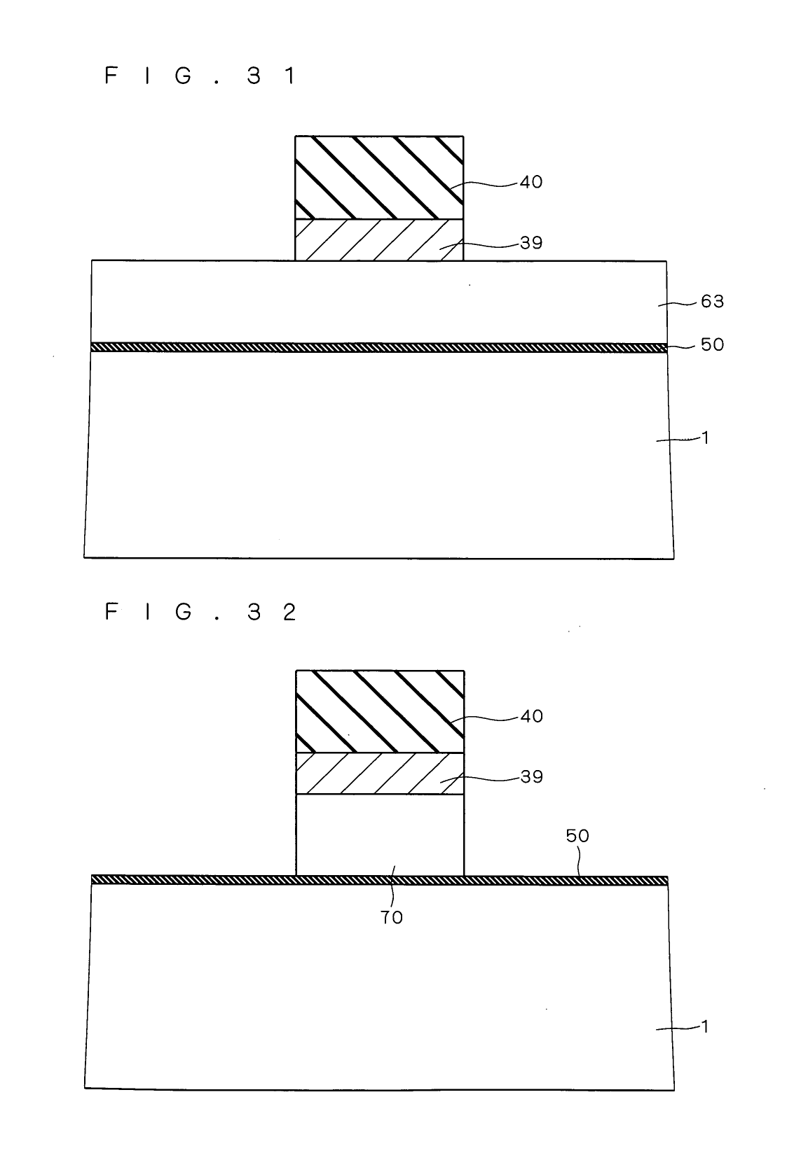

In the following, manufacturing methods will be described. FIGS. 23 to 29 are cross-sectional views showing a manufacturing method of the memory cell transistor according to the second embodiment in order of steps, and FIGS. 31 to 36 are cross-sectional views showing a manufacturing method of the transistor for the peripheral circuit according to the second embodiment in order of steps.

With reference to FIGS. 23 and 31, a silicon oxide film 25 having a thickness of approximately 8 to 12 nm, a polysilicon film 26 having a thickness of approximately 50 to 150 nm, a silicon oxide film 27 having a thickness of approximately 2 to 4 nm, a silicon nitride film 28 having a thickness of approximately 5 to 15 nm, and a silicon oxide film 29 having a thickness of approximately 5 to 15 nm are formed in this order on the upper surface of the silicon substrate 1 in the memory cell array region. In addition, a silicon oxide film 50 having a thickness of approximately 20 to 200 nm is formed on the upper surface of the silicon substrate 1 in the peripheral circuit region.

Next, a polysilicon film 63 having a thickness of approximately 50 to 150 nm, a tungsten film having a thickness of approximately 20 to 60 nm, and a silicon nitride film having a thickness of approximately 200 to 300 nm are formed in this order on the entire surface in accordance with a CVD method. Next, the tungsten film and the silicon nitride film are patterned in accordance with a photolithographic method and an anisotropic etching method. Thus, a first layered structure including the tungsten film 59 and the silicon nitride film 60 is formed on the upper surface of the polysilicon film 63 in the memory cell array region, and a second layered structure including the tungsten film 39 and the silicon nitride film 40 is formed on the polysilicon film 63 in the peripheral circuit region.

The gate structure of a memory cell transistor is defined by the first layered structure, and the gate structure of a transistor for a peripheral circuit is defined by the second layered structure. Accordingly, both the gate structure of a memory cell transistor and the gate structure of a transistor for a peripheral circuit can be defined in one lithographic process in accordance with the manufacturing method of the semiconductor device according to the second embodiment in the same manner as in the manufacturing method of the semiconductor device according to the first embodiment; thus, reduction in cost can be achieved.

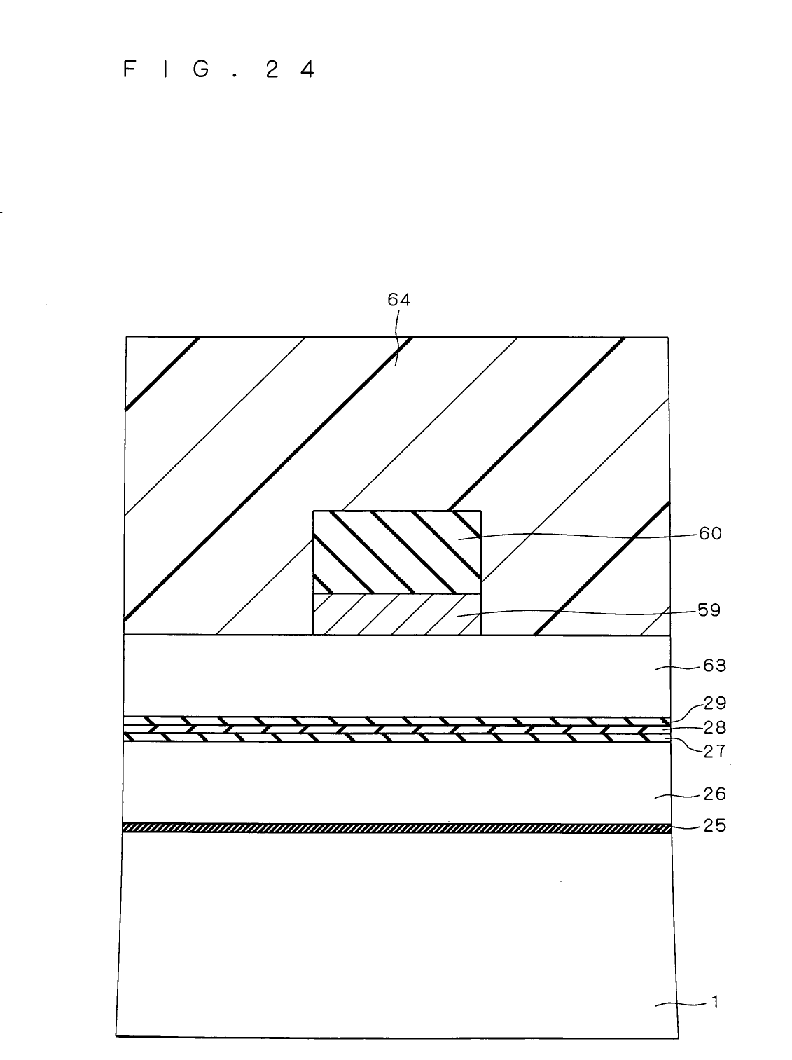

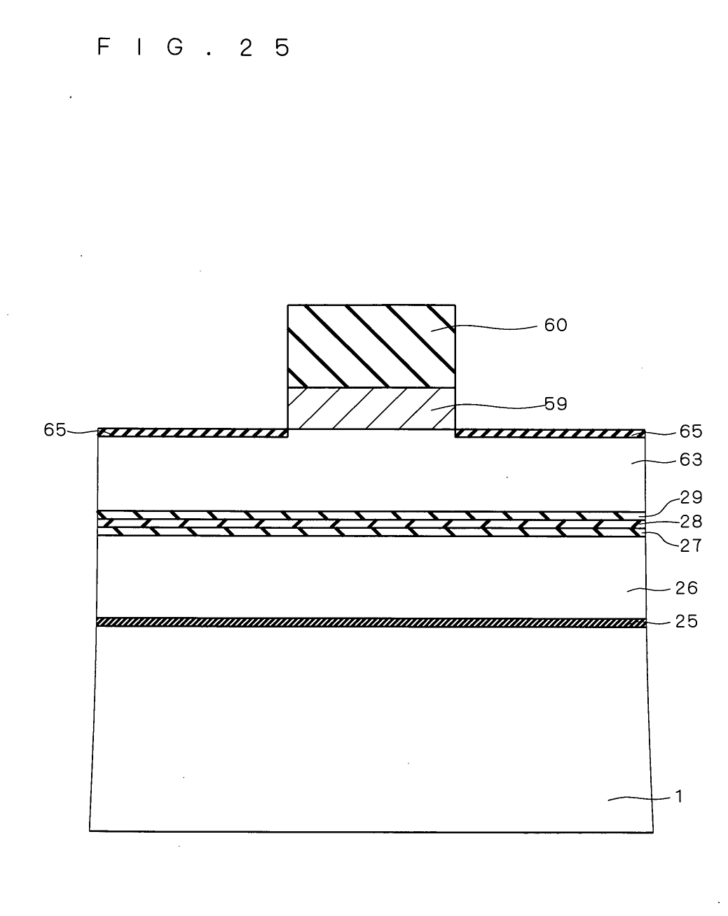

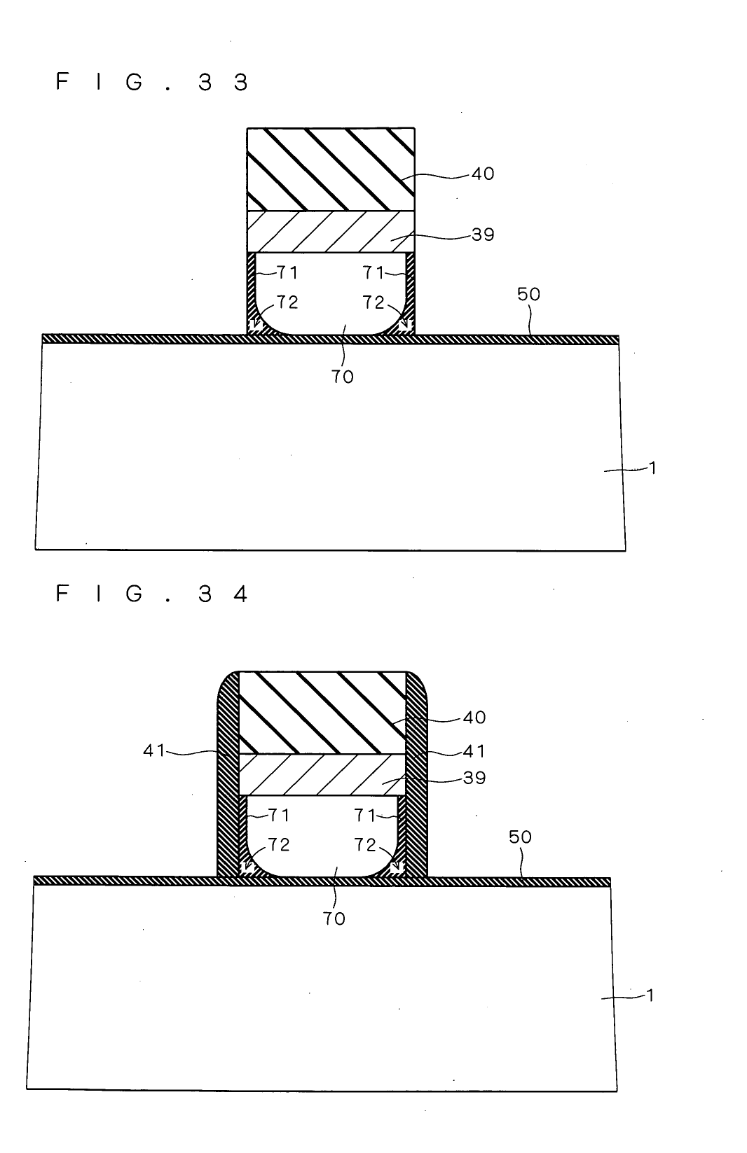

Next, with reference to FIGS. 24 and 32, a photoresist 64 is formed so as to cover the memory cell array region in accordance with a photolithographic method. Next, the photoresist 64 and the silicon nitride 40 are used as etching masks, and the polysilicon film 63 in the peripheral circuit region is etched in accordance with an anisotropic etching method. Thus, the portion of the polysilicon film 63 which is not etched becomes the polysilicon film 70. After that, the photoresist 64 is removed Next, with reference to FIGS. 25 and 33, thermal oxidation is carried out under process conditions (1000° C., growth amount of thermal oxide film: 13 to 15 nm) which are optimal for a transistor for a peripheral circuit. Here, in the case of a polymetal gate device, such as in the second embodiment, it is desirable to use selective oxide conditions (approximately 800 to 900° C.), in order to avoid oxidation of the tungsten films 59 and 39. Thus, a thermal oxide film 65 is formed in the upper surface of the polysilicon film 63 in the memory cell array region and, also, thermal oxide films 71 are formed in the side surfaces of the polysilicon film 70 in the peripheral circuit region. The thermal oxide films 71 have bird's beaks 72.

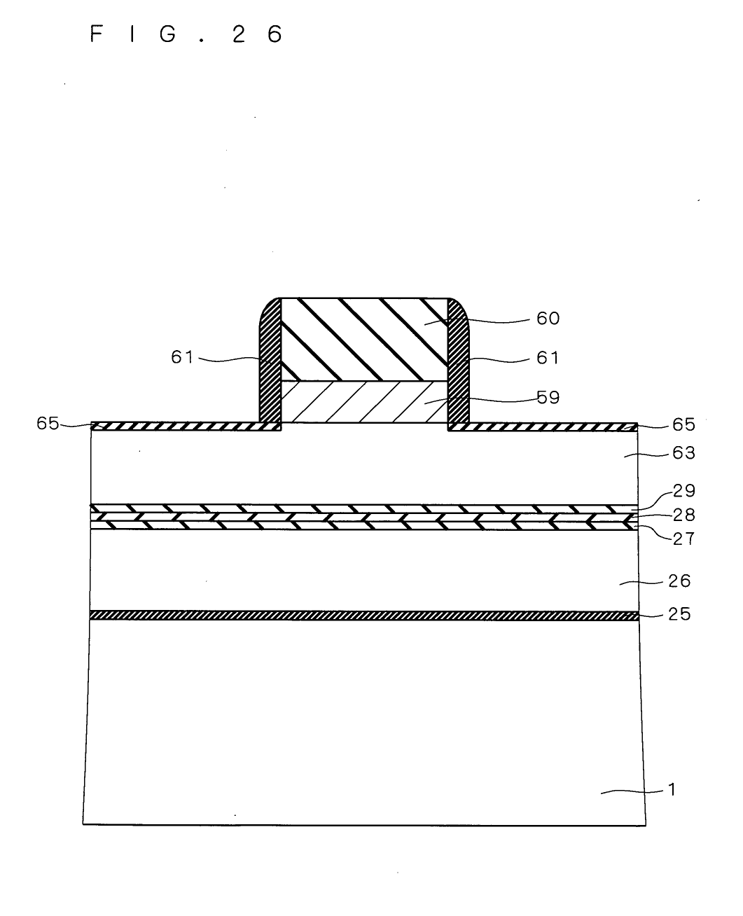

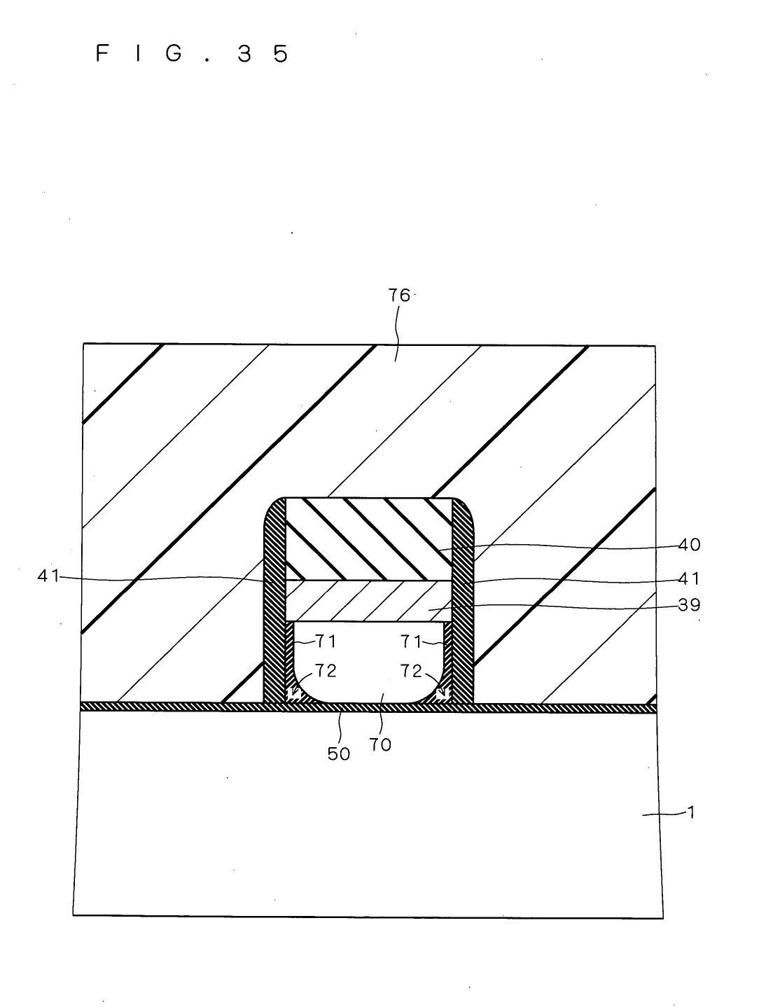

Next, with reference to FIGS. 26 and 34, an insulting film which has a thickness of approximately 10 to 30 nm and which is made of a material having an oxygen blocking property (for example, silicon nitride film) is formed on the entire surface in accordance with a CVD method, and after that, etch-back is carried out. Thus, sidewall insulating films 61 are formed in the memory cell array region, and sidewall insulating films 41 are formed in the peripheral circuit region.

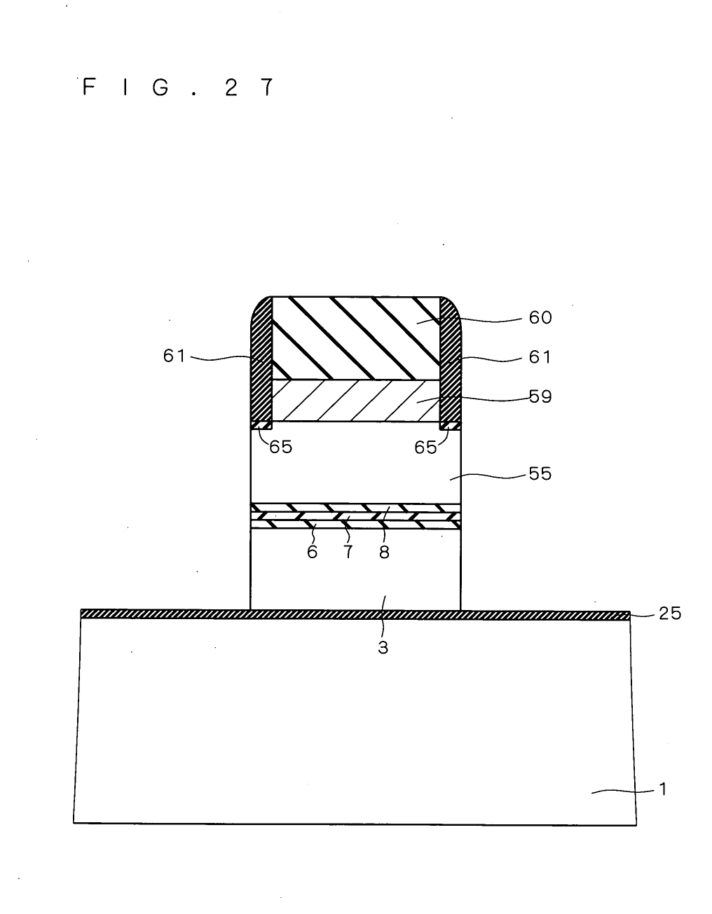

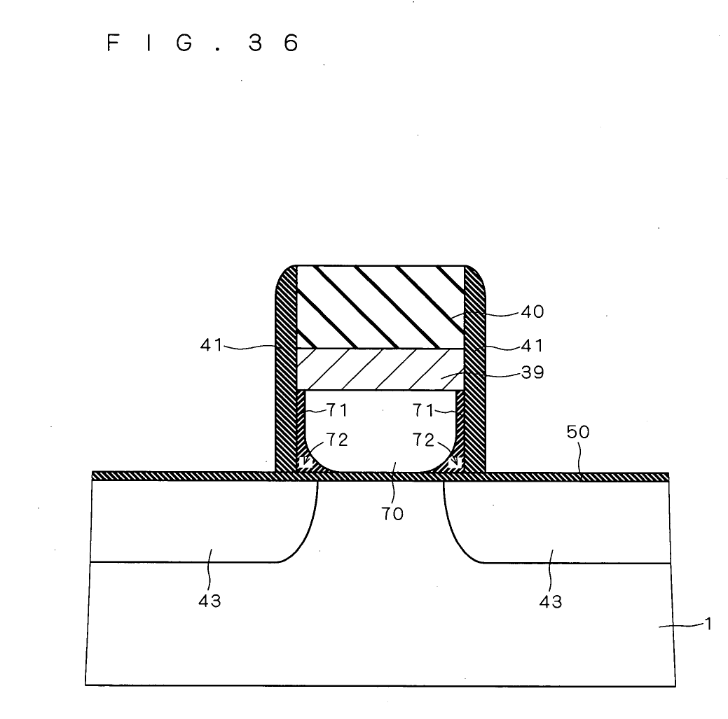

Next, with reference to FIGS. 27 and 35, a photoresist 76 is formed so as to cover the peripheral circuit region in accordance with a photolithographic method. Next, the photoresist 76, the silicon nitride film 60 and the sidewall insulating films 61 are used as etching masks, and the thermal oxide film 65, the polysilicon film 63, the silicon oxide film 29, the silicon nitride film 28, the silicon oxide film 27 and the polysilicon film 26 are etched in this order in accordance with an anisotropic etching method. Thus, the portions of the polysilicon film 63, the silicon oxide film 29, the silicon nitride film 28, the silicon oxide film 27 and the polysilicon film 26 which are not etched become the polysilicon film 55, the silicon oxide film 8, the silicon nitride film 7, the silicon oxide film 6 and the floating gate 3, respectively. After that, the photoresist 76 is removed. As shown in FIG. 27, portions of the thermal oxide film 65 remain at the upper surface ends of the polysilicon film 55.

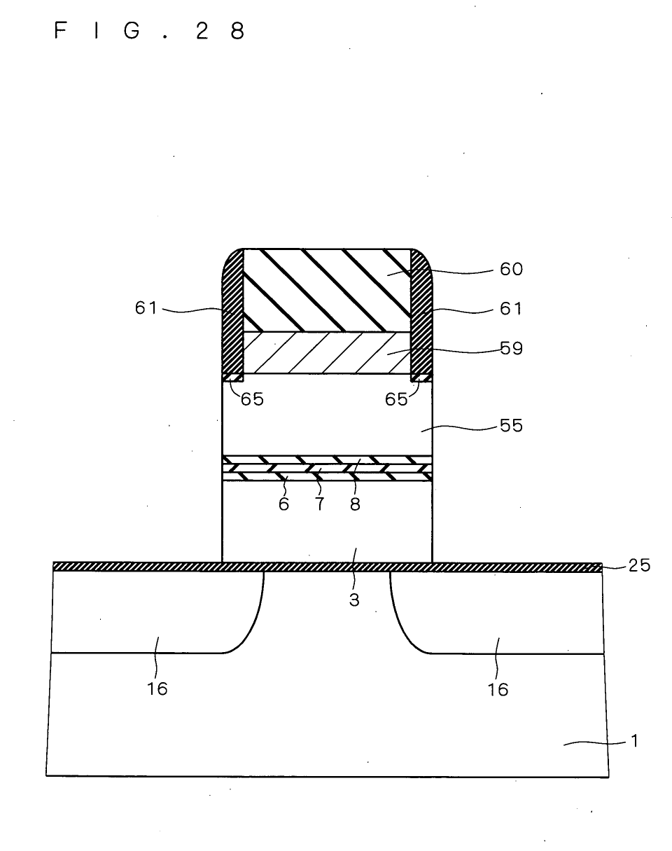

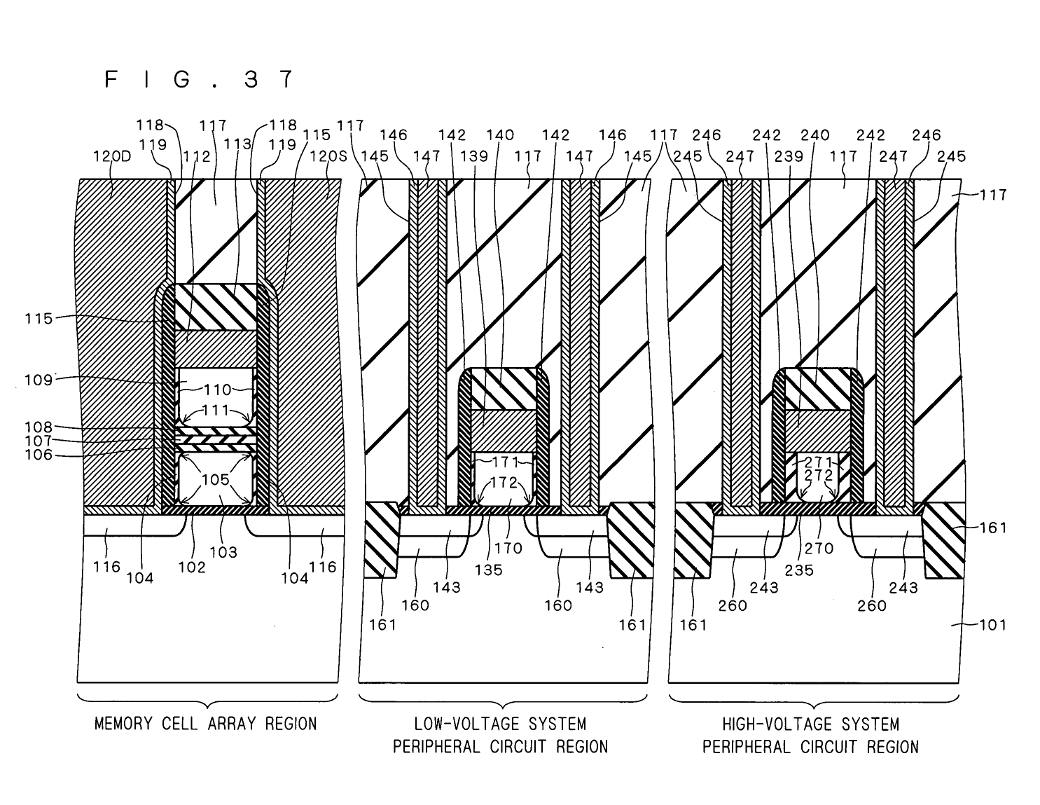

Next, with reference to FIGS. 28 and 36, impurities are introduced into the upper surface portion of the silicon substrate 1 through the silicon oxide films 25 and 50 in accordance with an ion implantation method. Thus, source and drain regions 16 are formed in the upper surface portion of the silicon substrate 1 in the memory cell array region and, also, source and drain regions 43 are formed in the upper surface portion of the silicon substrate 1 in the peripheral circuit region.

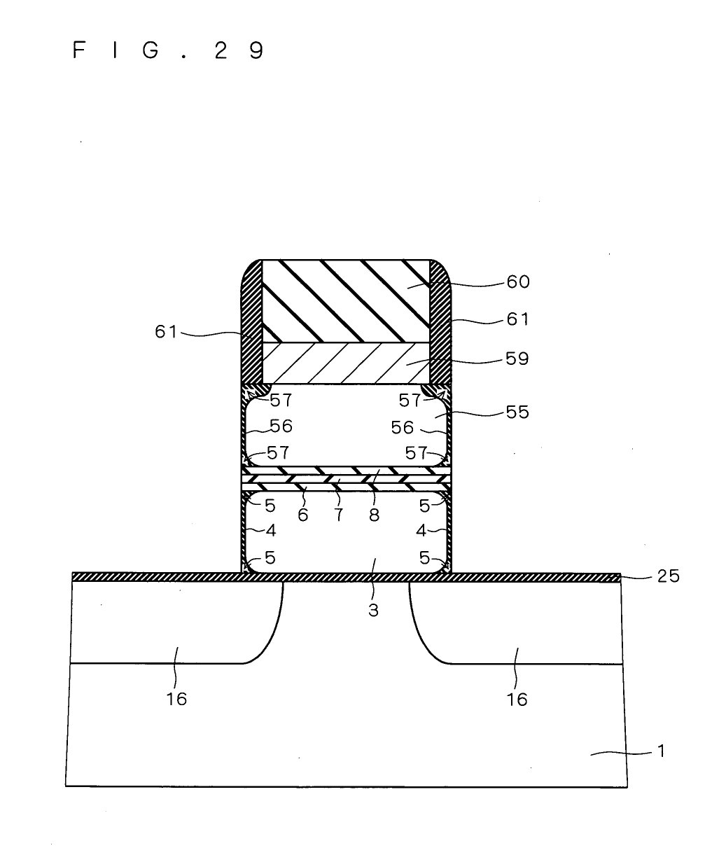

Next, with reference to FIG. 29, thermal oxidation is carried out under process conditions (1000° C., growth amount of thermal oxide film: 8 to 10 nm) which are optimal for a memory cell transistor. Here, in the case of a polymetal gate device, such as in the second embodiment, it is desirable to use selective oxidation conditions (approximately 800 to 900° C.), in order to avoid oxidation of the tungsten film 59. Thus, thermal oxide films 4 are formed in the side surfaces of the floating gate 3, and, also, thermal oxide films 56 are formed in the side surfaces of the polysilicon film 55, in the memory cell array region. The thermal oxide films 4 have bird's beaks 5, and the thermal oxide films 56 have bird's beaks 57. The bird's beaks 57 which are formed at the upper surface ends of the polysilicon films 55 are greater than the bird's beaks 57 which are formed at the bottom surface ends of the polysilicon films 55, because the thermal oxide films 65 remain at the upper surface ends of the polysilicon film 55.

At this time, as shown in FIG. 36, sidewall insulating films 41 are formed on the side surfaces of the polysilicon film 70 in the peripheral circuit region and, in addition, the sidewall insulating films 41 are made of a material having an oxygen blocking property. Therefore, the polysilicon film 70 is not oxidized through thermal oxidation for the formation of the thermal oxide films 4 and 56, so that it is possible to avoid a state where the thickness and the size of the bird's beaks 72 in the thermal oxide films 71 that are already formed fluctuate.

After that, the same process as in the manufacturing method of the semiconductor device according to the first embodiment is carried out, so that the structures shown in FIGS. 22 and 30 are obtained.

With the manufacturing method of the semiconductor device according to the second embodiment, the step of forming thermal oxide films 4 in the side surfaces of the floating gate 3 of a memory cell transistor (FIG. 29) and the step of forming thermal oxide films 71 in the side surfaces of the gate electrode (polysilicon film 70) of a transistor for a peripheral circuit (FIG. 33) are carried out as separate steps. Consequently, the bird's beaks 5 in the thermal oxide films 4 can be made smaller than the bird's beaks 72 in the thermal oxide films 71. As a result, with the semiconductor device according to the second embodiment, deterioration in transistor characteristics, e.g., the lead current is reduced, can be avoided in a memory cell transistor, and concentration of the electrical field at the gate edges can be avoided in a transistor for a peripheral circuit.

In addition, with the semiconductor device according to the second embodiment, the dimensions of the floating gate 3 in the gate length direction are greater than the respective dimensions of the tungsten film 59 and the silicon nitride film 60 in the gate length direction, and are equal to the dimensions of the control gate (polysilicon film 55) in the gate length direction. In addition, the bird's beaks 57 which are formed at the bottom surface ends of the polysilicon film 55 are smaller than the bird's beaks 11 (see FIG. 1) which are formed at the bottom surface ends of the polysilicon film 9. Accordingly, in comparison with the semiconductor device according to the first embodiment, the area where the floating gate 3 and the control gate face each other across the ONO film can be expanded; therefore, the coupling ratio between the floating gate 3 and the control gate can be increased. As a result, read-out and write-in functions can be improved, and it becomes possible to perform read-out and write-in at lower voltages.

Here, though in the first and second embodiments, examples where the present invention is applied to objects such as flash memory devices which adopts a polymetal gate structure are described, it is possible to apply the present invention to any semiconductor device having a floating gate and a control gate of which the side surfaces are thermally oxidized. This is the same for a third embodiment which will be described later.

### Third Embodiment

In the first and second embodiments, description has been given that the size of bird's beaks in a memory cell transistor is different from the size of bird's beaks in a transistor for a peripheral circuit. Transistors for peripheral circuits, however, can be divided into transistors for low-voltage system peripheral circuits that are driven by a relatively low voltage, and transistors for high-voltage system peripheral circuits that are driven by a relatively high voltage.

As for the transistor for a low-voltage system peripheral circuit, in the case where the gate length becomes 0.20 μm or less as a result of miniaturization of the semiconductor device, transistor characteristics deteriorate, in the same manner as in a memory cell transistor. Meanwhile, as for the transistor for a high-voltage system peripheral circuit, a high voltage (5 to 40 V) is applied to the gate electrode; therefore, it is necessary to make the bird's beaks large so as to suppress the concentration of the electrical field at the gate edges.

Therefore, in the third embodiment, description will be given of a semiconductor device where the bird's beaks in the thermal oxide films are made different from each other in a memory cell transistor and a transistor for a low-voltage system peripheral circuit and in a transistor for a high-voltage system peripheral circuit, and thereby, deterioration in the transistor characteristics of the memory cell transistor and the transistor for the low-voltage system peripheral circuit, and concentration of the electrical field at the gate edges of the transistor for the high-voltage system peripheral circuit can both be avoided, as well as a manufacturing method thereof.

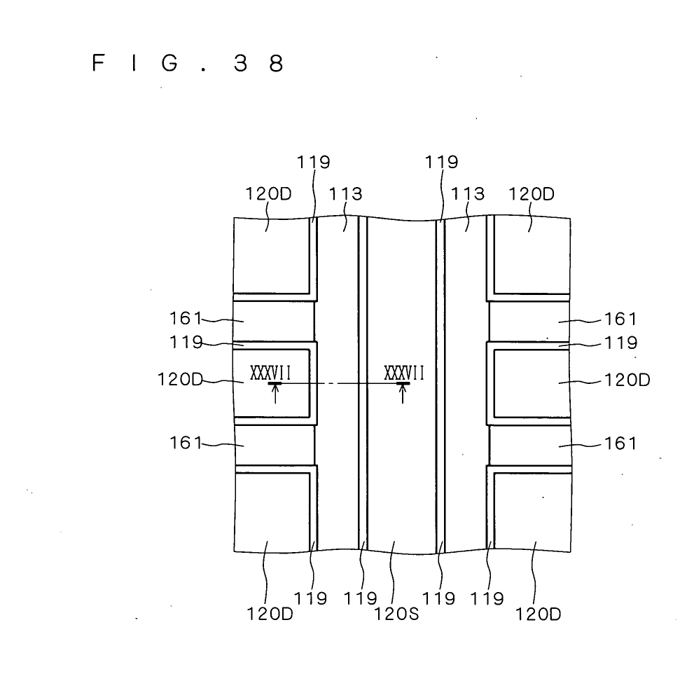

FIG. 37 is a cross-sectional view showing the structure of a semiconductor device according to the third embodiment of the present invention. A silicon substrate 101 is provided with a memory cell array region where memory cell transistors are formed, a low-voltage system peripheral circuit region where transistors for a low-voltage system peripheral circuit are formed, and a high-voltage system peripheral circuit region where transistors for a high-voltage system peripheral circuit are formed.

In the memory cell array region, a tunnel oxide film 102 is formed on the upper surface of the silicon substrate 101. A floating gate 103 is formed on the upper surface of the tunnel oxide film 102. Thermal oxide films 104 are formed in the side surfaces of the floating gate 103. A silicon oxide film 106, a silicon nitride film 107 and a silicon oxide film 108 are formed in this order on the upper surface of the floating gate 103. An insulating film having a three-layer structure where the silicon nitride film 107 is sandwiched between the silicon oxide films 106 and 108 is also referred to as “ONO film”.

A control gate is formed on the upper surface of the silicon oxide film 108. The control gate has a polysilicon film 109 that is formed on the upper surface of the silicon oxide film 108, and a tungsten film 112 that is formed on the upper surface of the polysilicon film 109. Thermal oxide films 110 are formed in the side surfaces of the polysilicon film 109. A silicon nitride film 113 is formed on the upper surface of the tungsten film 112.

Bird's beaks 105 are respectively formed in the thermal oxide films 104 at the bottom surface ends of the floating gate 103, which are defined by the upper surface of the tunnel oxide film 102 and the side surfaces of the floating gate 103, and at the upper surface ends of the floating gate 103, which are defined by the bottom surface of the silicon oxide film 106 and the side surfaces of the floating gate 103. In addition, bird's beaks 111 are formed in the thermal oxide films 110 at the bottom surface ends of the control gate, which are defined by the upper surface of the silicon oxide film 108 and the side surfaces of the polysilicon film 109.

Sidewall insulating films 115 are formed on the upper surface of the tunnel oxide film 102 and on the respective side surfaces of the floating gate 103, the ONO film, the control gate and the silicon nitride film 113.

LDD (Lightly Doped Drain) regions 116 are formed in the upper surface portion of the silicon substrate 101 so as to face each other with a channel formation region that is formed beneath the floating gate 103 in between.

An interlayer insulating film 117 is formed so as to cover the memory cell transistor, and contact holes 118 are formed in the interlayer insulating film 117 so as to reach the upper surface of the LDD regions 116. The inside of the contact holes 118 is filled in with a barrier metal film 119 and tungsten films 120S and 120D.

In the low-voltage system peripheral circuit region, a gate insulating film 135 is formed on the upper surface of the silicon substrate 101. A gate electrode is formed on the upper surface of the gate insulating film 135. The gate electrode has a polysilicon film 170 that is formed on the upper surface of the gate insulating film 135 and a tungsten film 139 that is formed on the upper surface of the polysilicon film 170. Thermal oxide films 171 are formed in the side surfaces of the polysilicon film 170. A silicon nitride film 140 is formed on the upper surface of the tungsten film 139.

Bird's beaks 172 are formed in the thermal oxide films 171 at the bottom surface ends of the gate electrode, which are defined by the upper surface of the gate insulating film 135 and the side surfaces of the polysilicon film 170. The dimension of the thermal oxide films 171 in a gate length direction are the same as those of the thermal oxide films 104 and 110 in the gate length direction. In addition, the size of the bird's beaks 172 is the same as those of the bird's beaks 105 and 111.

Sidewall insulating films 142 are formed on the upper surface of the gate insulating film 135 and on the respective side surfaces of the gate electrode and the silicon nitride film 140.

LDD regions 143 and source and drain regions 160 are formed in the upper surface portion of the silicon substrate 101 in such a manner as to face each other with a channel formation region that is formed beneath the gate electrode in between.

The interlayer insulating film 117 is formed so as to cover the transistor for the low-voltage system peripheral circuit, and contact holes 145 are formed in the interlayer insulating film 117 so as to reach the upper surface of the source and drain regions 160. The inside of the contact holes 145 is filled in with a barrier metal film 146 and a tungsten film 147.

In the high-voltage system peripheral circuit region, a gate insulating film 235 is formed on the upper surface of the silicon substrate 101. A gate electrode is formed on the upper surface of the gate insulating film 235. The gate electrode has a polysilicon film 270 that is formed on the upper surface of the gate insulating film 235 and a tungsten film 239 that is formed on the upper surface of the polysilicon film 270. Thermal oxide films 271 are formed in the side surfaces of the polysilicon film 270. A silicon nitride film 240 is formed on the upper surface of the tungsten film 239.

Bird's beaks 272 are formed in the thermal oxide films 271 at the bottom surface ends of the gate electrode, which are defined by the upper surface of the gate insulating film 235 and the side surfaces of the polysilicon film 270. The dimension of the thermal oxide films 271 in the gate length direction is greater than those of the thermal oxide films 104, 110 and 171 in the gate length direction. In addition, the bird's beaks 272 are greater than the bird's beaks 105, 111 and 172.

Sidewall insulating films 242 are formed on the upper surface of the gate insulating film 235 and on the respective side surfaces of the gate electrode and the silicon nitride film 240.

LDD regions 243 and source and drain regions 240 are formed in the upper surface portion of the silicon substrate 101 in such a manner as to face each other with a channel formation region that is formed beneath the gate electrode in between.

The interlayer insulating film 117 is formed so as to cover the transistor for the high-voltage system peripheral circuit, and contact holes 245 are formed in the interlayer insulating film 117 so as to reach the upper surface of the source and drain regions 260. The inside of the contact holes 245 is filled in with a barrier metal film 246 and a tungsten film 247.

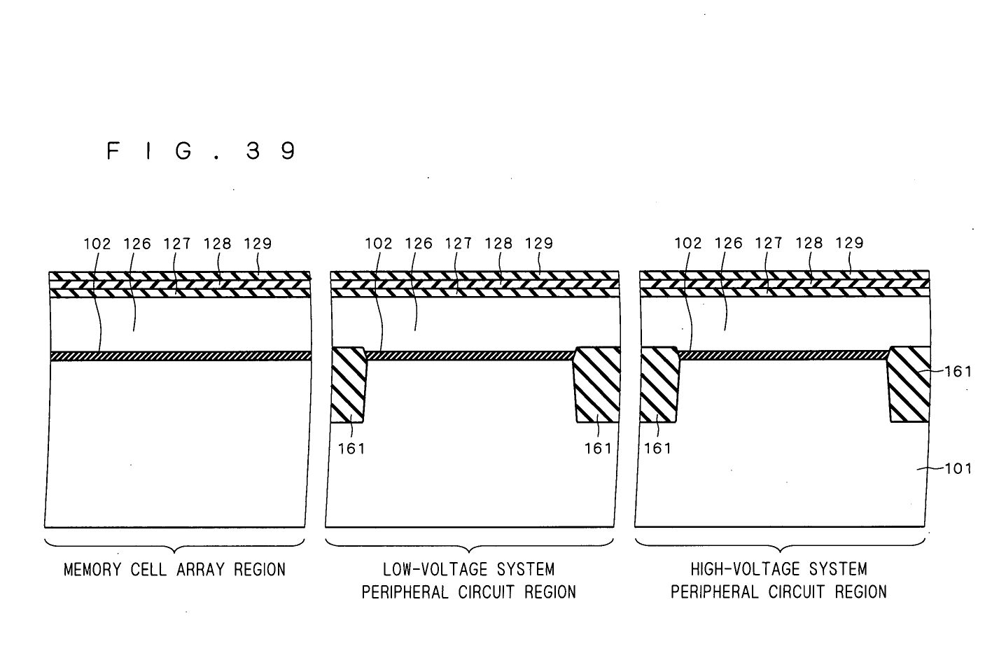

FIG. 38 is a top view showing the structure of the memory cell array region in the structure of the semiconductor device according to the third embodiment. The structure of the portion of the memory cell array region in the cross sectional structure shown in FIG. 37 corresponds to the cross sectional structure taken along line XXXVII-XXXVII shown in FIG. 38. Here, the interlayer insulating film 117 is not shown in FIG. 38.

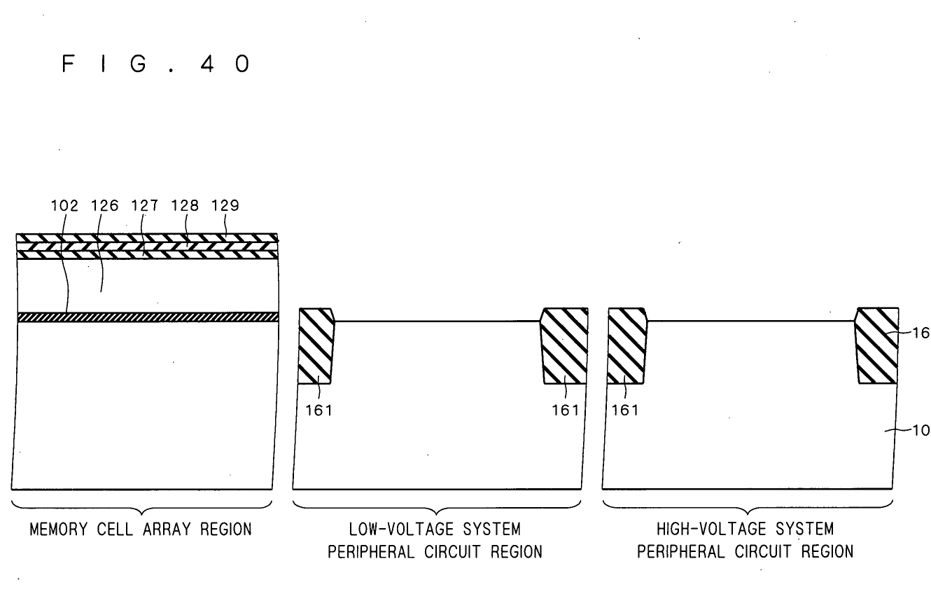

In the following, a manufacturing method will be described. FIGS. 39 to 49 are cross-sectional views corresponding to FIG. 37 showing a manufacturing method of the semiconductor device according to the third embodiment in order of steps.

With reference to FIG. 39, a well (not shown) is formed in the silicon substrate 101 in accordance with an ion implantation method, and after that, element isolation insulating films 161 are formed in upper surface portions of the silicon substrate 101. Next, a tunnel oxide film 102 having a thickness of approximately 8 to 12 nm and a polysilicon film 126 having a thickness of approximately 50 to 150 nm are formed in this order on the entire upper surface of the silicon substrate 101. Next, the polysilicon film 126 in the memory cell array region is patterned, so that the polysilicon films 126 are divided for the respective memory cells that are aligned along word lines. Here, this step is not shown in FIG. 39. Next, a silicon oxide film 127 having a thickness of approximately 2 to 4 nm, a silicon nitride film 128 having a thickness of approximately 5 to 15 nm, and a silicon oxide film 129 having a thickness of approximately 5 to 15 nm are formed in this order on the entire upper surface of the polysilicon film 126.

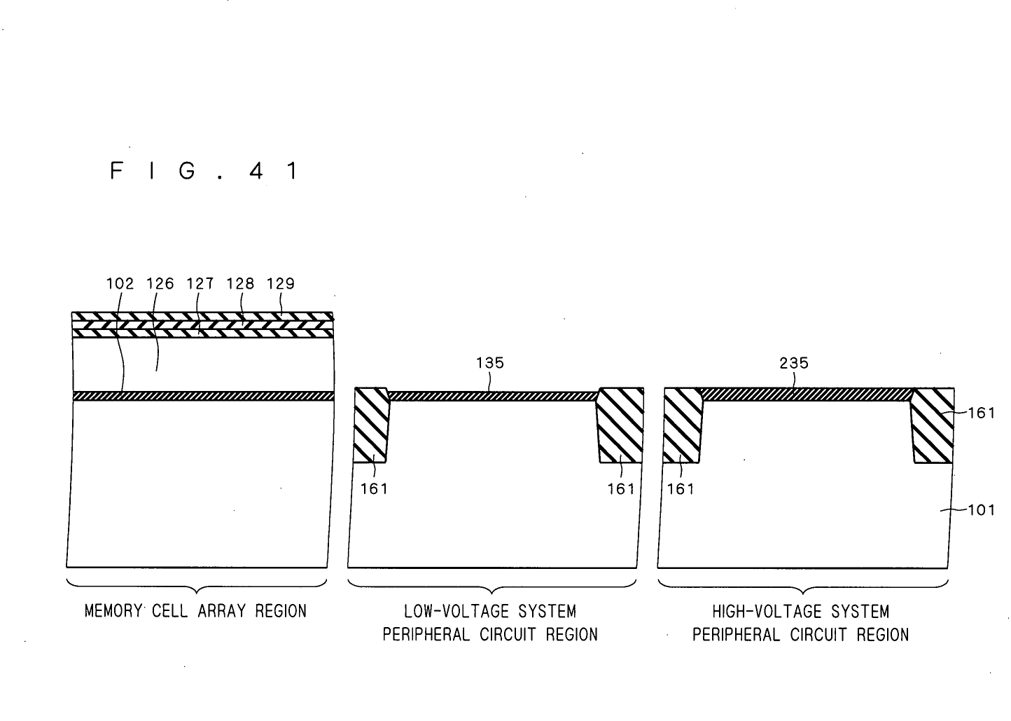

Next, with reference to FIG. 40, the tunnel oxide film 102, the polysilicon film 126, the silicon oxide films 127 and 129, and the silicon nitride film 128 in the low-voltage system peripheral circuit region and the high-voltage system peripheral circuit region are removed.

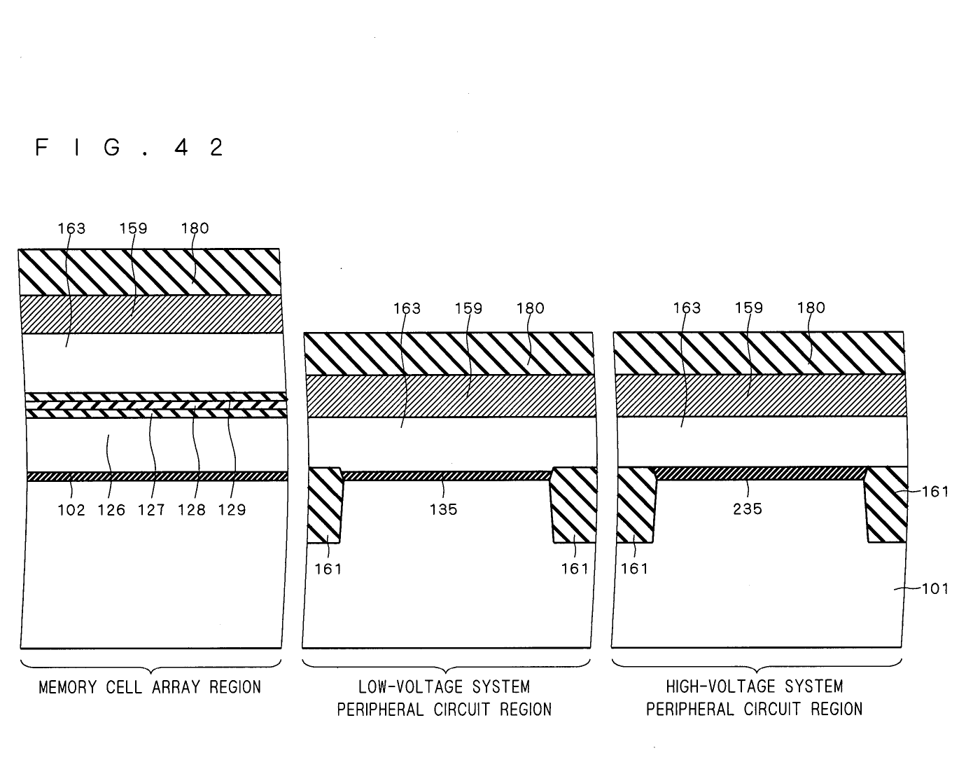

Next, with reference to FIG. 41, a gate insulating film 135 having a thickness of approximately 3 to 6 nm is formed on the upper surface of the silicon substrate 101 in the low-voltage system peripheral circuit region. Next, a gate insulating film 235 having a thickness of approximately 10 to 30 nm is formed on the upper surface of the silicon substrate 101 in the high-voltage system peripheral circuit region.

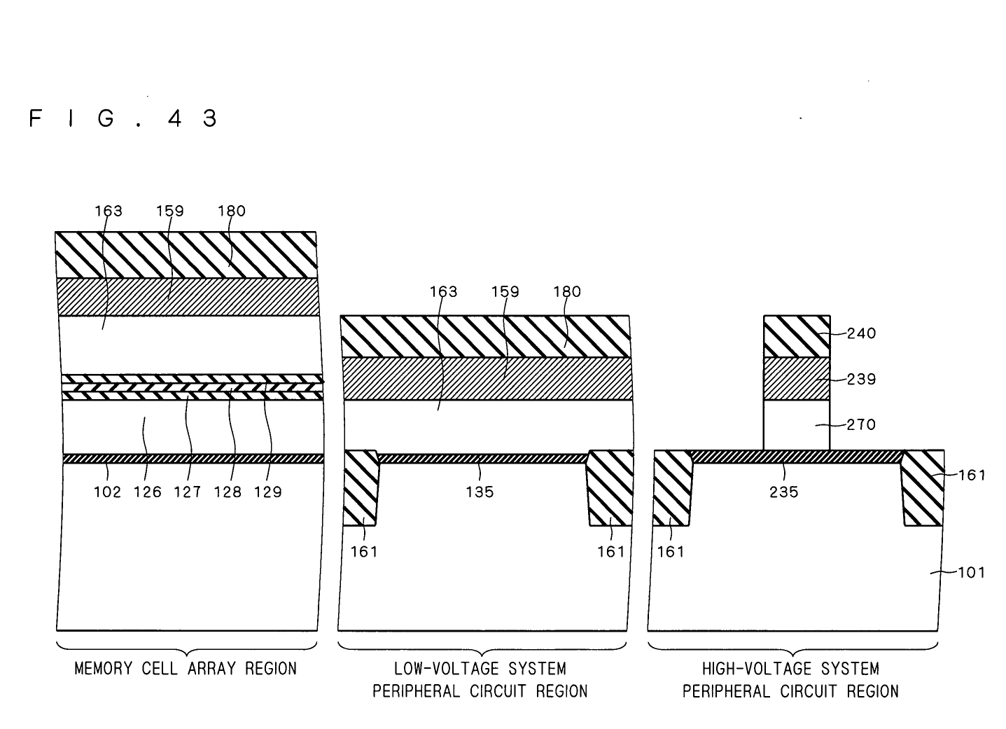

Next, with reference to FIG. 42, a polysilicon film 163 having a thickness of approximately 50 to 150 nm, a tungsten film 159 having a thickness of approximately 20 to 60 nm, and a silicon nitride film 180 having a thickness of approximately 200 to 300 nm are formed in this order on the entire surface.

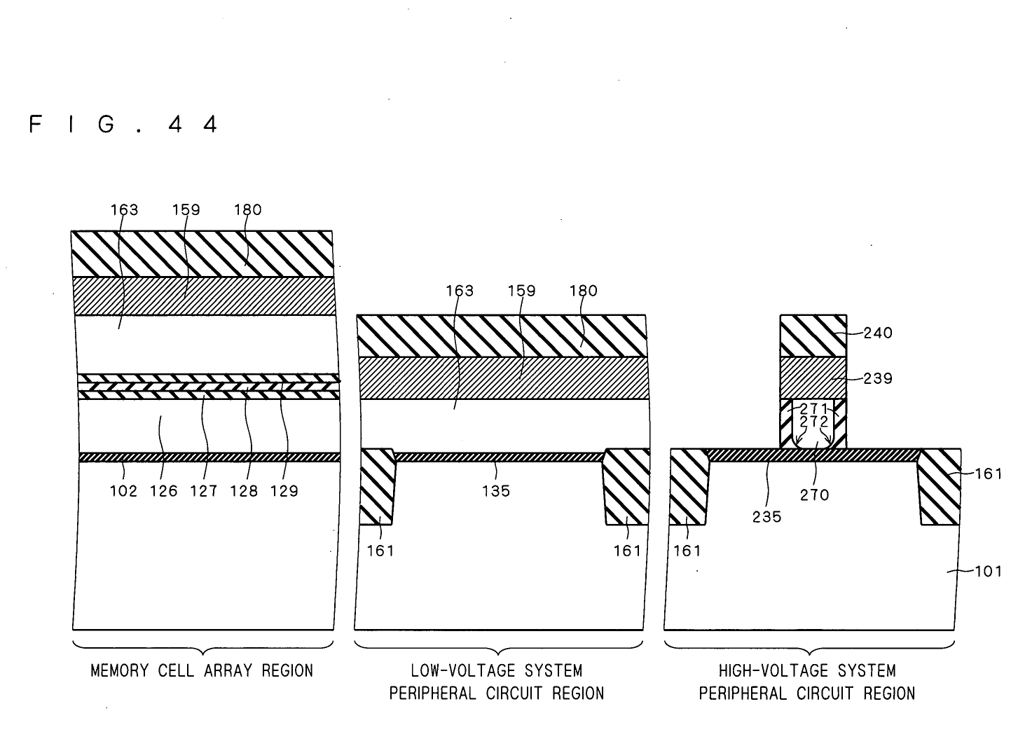

Next, with reference to FIG. 43, the polysilicon film 163, the tungsten film 159 and the silicon nitride film 180 in the high-voltage system peripheral circuit region are patterned in accordance with a photolithographic method and an anisotropic etching method. Thus, a structure where the polysilicon film 270, the tungsten film 239 and the silicon nitride film 240 are layered in this order is formed on the gate insulating film 235 in the high-voltage system peripheral circuit region.

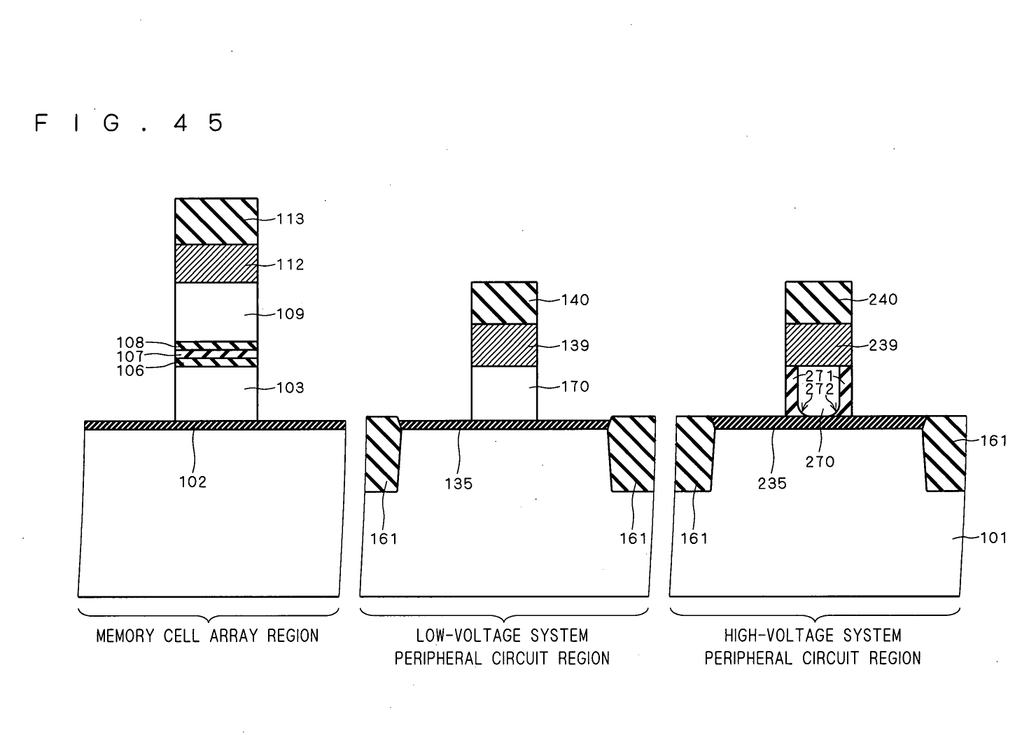

Next, with reference to FIG. 44, thermal oxidation is carried out under process conditions (1000° C., growth amount of thermal oxide film: approximately 13 to 15 nm) which are optimal for a transistor for the high-voltage system peripheral circuit. Here, in the case of a polymetal gate device, such as in the third embodiment, it is desirable to use selective oxidation conditions (approximately 800 to 900° C.), in order to avoid oxidation of the tungsten film 239. As a result, thermal oxide films 271 are formed in the side surfaces of the polysilicon film 270 in the high-voltage system peripheral circuit region. The thermal oxide films 271 have bird's beaks 272. The length of the bird's beaks is, for example, approximately 25 to 30 nm.

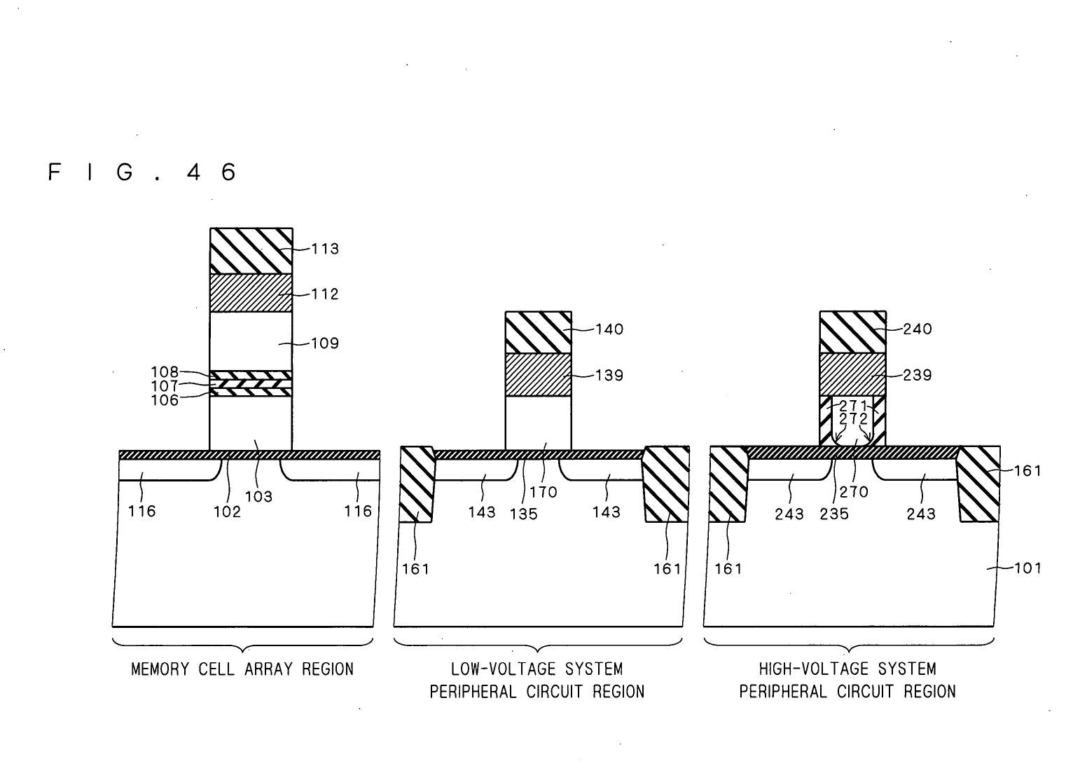

Next, with reference to FIG. 45, the polysilicon films 126 and 163, the tungsten film 159, the silicon oxide films 127 and 129, and the silicon nitride films 128 and 180 in the memory cell array region are patterned in accordance with a photolithographic method and an anisotropic etching method. At the same time as this, the polysilicon film 163, the tungsten film 159 and the silicon nitride film 180 in the low-voltage system peripheral circuit region are patterned. Thus, a structure where the floating gate 103, the silicon oxide film 106, the silicon nitride film 107, the silicon oxide film 108, the polysilicon film 109, the tungsten film 112 and the silicon nitride film 113 are layered in this order is formed on the tunnel oxide film 102 in the memory cell array region. In addition, a structure where the polysilicon film 170, the tungsten film 139 and the silicon nitride film 140 are layered in this order is formed on the gate insulating film 135 in the low-voltage system peripheral circuit region.

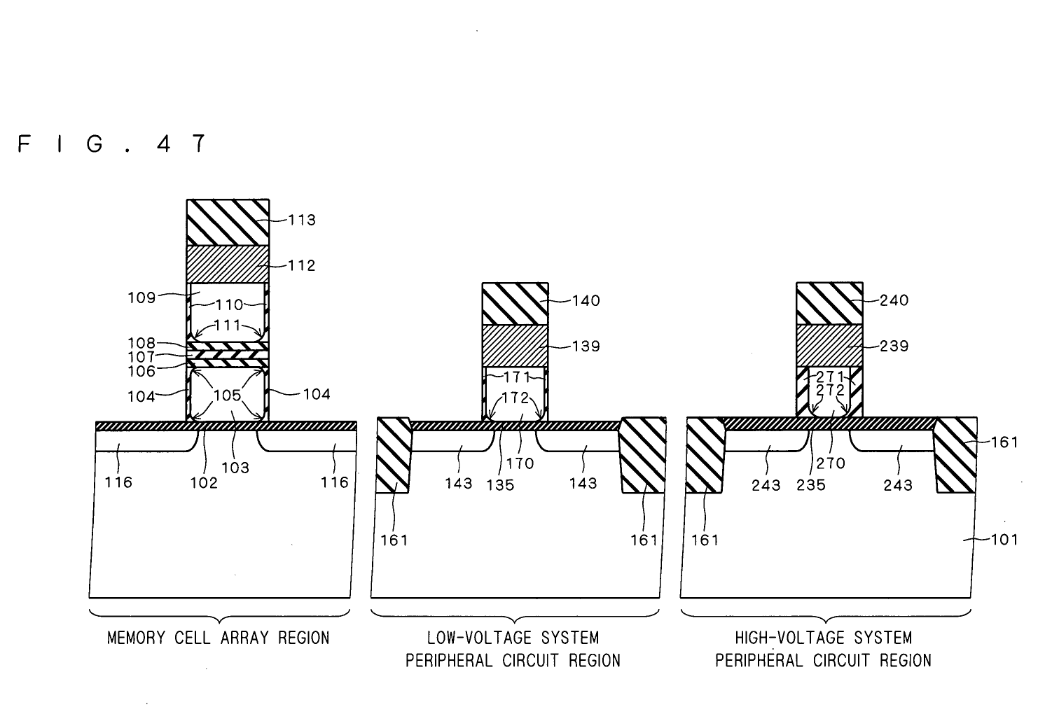

Next, with reference to FIG. 46, impurities are introduced into upper surface portions of the silicon substrate 101 through the tunnel oxide film 102 and the gate insulating films 135 and 235 in accordance with an ion implantation method. Thus, LDD regions 116 are formed in the upper surface portion of the silicon substrate 101 in the memory cell array region, LDD regions 143 are formed in the upper surface portion of the silicon substrate 101 in the low-voltage system peripheral circuit region, and LDD regions 243 are formed in the upper surface portion of the silicon substrate 101 in the high-voltage system peripheral circuit region.

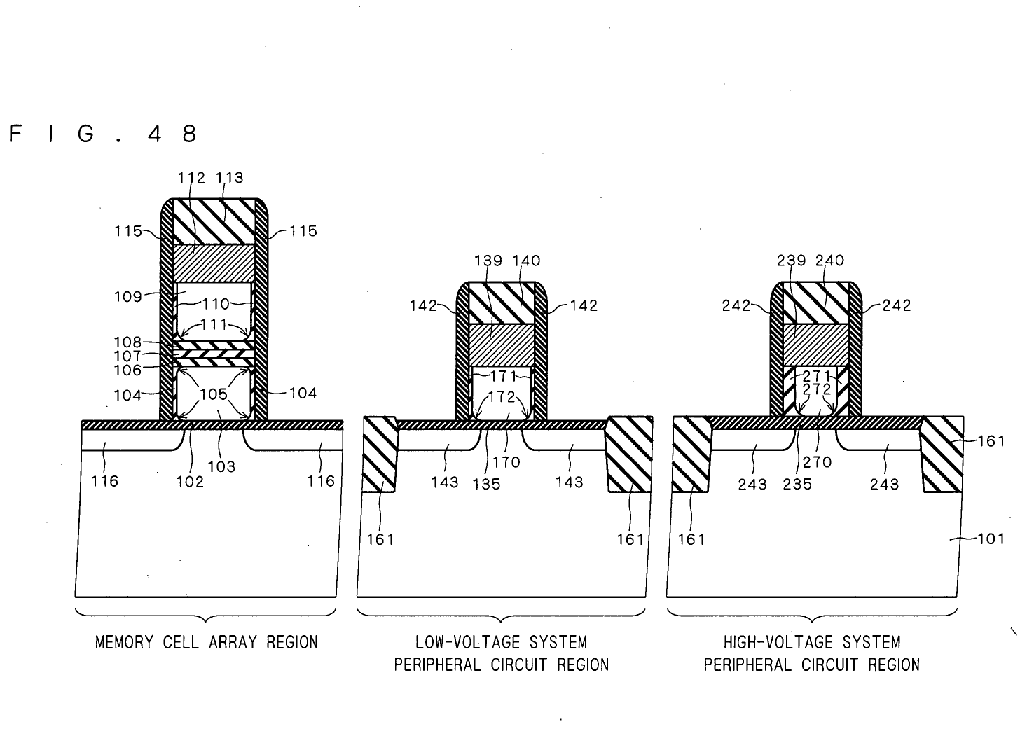

Next, with reference to FIG. 47, thermal oxidation is carried out under process conditions (1000° C., growth amount of thermal oxide film: 8 to 10 nm) which are optimal for a memory cell transistor and a transistor for the low-voltage system peripheral circuit. Here, in the case of a polymetal gate device, such as in the third embodiment, it is desirable to use selective oxide conditions (approximately 800 to 900° C.), in order to avoid oxidation of the tungsten films 112, 139 and 239. Thus, thermal oxide films 104 are formed in the side surfaces of the floating gate 103 and, also, thermal oxide films 110 are formed in the side surfaces of the polysilicon film 109, in the memory cell array region. In addition, thermal oxide films 171 are formed in the side surfaces of the polysilicon film 170 in the low-voltage system peripheral circuit region. The thermal oxide films 104, 110 and 171 have bird's beaks 105, 111 and 172, respectively. The length of any of the bird's beaks is, for example, approximately 15 to 20 nm.

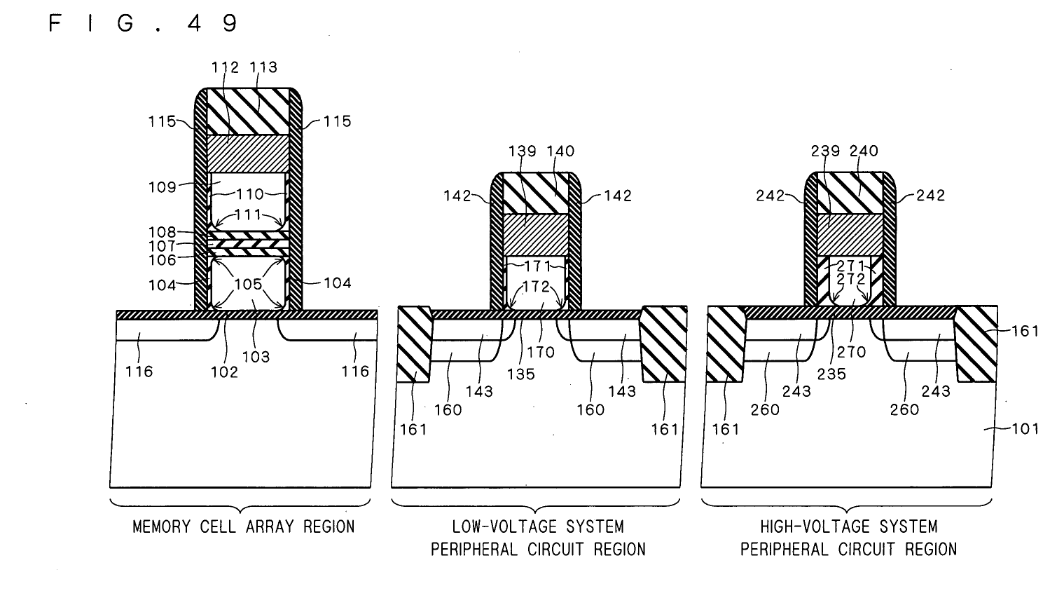

Next, with reference to FIG. 48, a silicon nitride film having a thickness of approximately 600 to 800 nm is formed on the entire surface, and after that, this silicon nitride film is etched back. Thus, sidewall insulating films 115 are formed in the memory cell array region, sidewall insulating films 142 are formed in the low-voltage system peripheral circuit region, and sidewall insulating films 242 are formed in the high-voltage system peripheral circuit region.

Next, with reference to FIG. 49, impurities are introduced into the upper surface portions of the silicon substrate 101 through the gate insulating films 135 and 235 in accordance with a photolithographic method and an ion implantation method. Thus, source and drain regions 160 are formed in the upper surface portion of the silicon substrate 101 in the low-voltage system peripheral circuit region, and source and drain regions 260 are formed in the upper surface portion of the silicon substrate 101 in the high-voltage system peripheral circuit region.

Next, an interlayer insulating film 117 which is made of BPTEOS or the like and has a thickness of approximately 500 to 1500 nm is formed on the entire surface. Next, contact holes 118, 145 and 245 are formed in the interlayer insulating film 117. Next, the inside of the contact holes 118, 145 and 245 is filled in with barrier metal films 119, 146 and 246 and tungsten films 120D, 120S, 147 and 247. As a result of the above-described steps, the structure shown in FIG. 37 is obtained.

With the manufacturing method of the semiconductor device according to the third embodiment, the step of forming the thermal oxide films 104 in the side surfaces of the floating gate 103 of a memory cell transistor (FIG. 47) and the step of forming the thermal oxide films 171 in the side surfaces of the gate electrode (polysilicon film 170) of a transistor for the low-voltage system peripheral circuit (FIG. 47) are carried out as steps which are different from the step of forming thermal oxide films 271 in the side surfaces of the gate electrode (polysilicon film 270) of a transistor for the high-voltage system peripheral circuit (FIG. 44). Consequently, the bird's beaks 105 and 172 in the thermal oxide films 104 and 171 can be made smaller than the bird's beaks 272 in the thermal oxide films 271. As a result, with the semiconductor device according to the third embodiment, deterioration in the transistor characteristics, e.g., the lead current is reduced, can be avoided in a memory cell transistor and a transistor for the low-voltage system peripheral circuit, and concentration of the electrical field at the gate edges can be avoided in a transistor for the high-voltage system peripheral circuit.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor substrate having a memory cell array region and a peripheral circuit region;
a first transistor formed in said memory cell array region; and
a second transistor formed in said peripheral circuit region, wherein said first transistor includes:
a floating gate formed on an upper surface of said semiconductor substrate via a first insulating film;
a control gate formed on said floating gate via a second insulating film; and
a first thermal oxide film formed in a side surface of said floating gate, said second transistor includes:
a gate electrode formed on said upper surface of said semiconductor substrate via a third insulating film; and
a second thermal oxide film formed in a side surface of said gate electrode, and a bird's beak in said first thermal oxide film is smaller than a bird's beak in said second thermal oxide film.

2. The semiconductor device according to claim 1, wherein
the dimension of said control gate in a gate length direction is smaller than the dimension of said floating gate in the gate length direction, and
sidewall insulating films made of a material having an oxygen blocking property are respectively formed on the upper surface of said second insulating film and on a side surface of said control gate as well as on a side surface of said gate electrode.

3. The semiconductor device according to claim 1, wherein
the dimension of said control gate in the gate length direction is equal to the dimension of said floating gate in the gate length direction.

4. The semiconductor device according to claim 3, further comprising:
a third thermal oxide film formed in a side surface of said control gate, wherein
a bird's beak in said third thermal oxide film is smaller than a bird's beak in said second thermal oxide film.

5. The semiconductor device according to claim 1, further comprising:
a third transistor formed in said peripheral circuit region, wherein
said second transistor is a transistor driven by a high voltage,
said third transistor is a transistor driven by a low voltage,
said third transistor includes:
a gate electrode formed on said upper surface of said semiconductor substrate via a fourth insulating film; and
a third thermal oxide film formed in a side surface of the gate electrode, and
a bird's beak in said third thermal oxide film is smaller than a bird's beak in said second thermal oxide film.

6. A manufacturing method of a semiconductor device, comprising the steps of:
(a) preparing a semiconductor substrate having a memory cell array region where a first transistor is to be formed, and a peripheral circuit region where a second transistor is to be formed;
(b) forming a first insulating film, a first conductive film and a second insulating film in this order on an upper surface of said semiconductor substrate in said memory cell array region;
(c) forming a third insulating film on said upper surface of said semiconductor substrate in said peripheral circuit region;
(d) forming a control gate of said first transistor partially on said second insulating film and, also, forming a gate electrode of said second transistor on said third insulating film;
(e) forming a first thermal oxide film having a first bird's beak in a side surface of said gate electrode;
(f) after completion of said step (e), forming a first sidewall insulating film made of a material having an oxygen blocking property on a side surface of said control gate and, also, forming a second sidewall insulating film made of said material on said side surface of said gate electrode;
(g) removing the portions of said first conductive film and said second insulating film which are not covered with said first sidewall insulating film and said control gate, wherein
the portion of said first conductive film which is not removed in said step (g) becomes a floating gate of said first transistor; and
(h) forming a second thermal oxide film having a second bird's beak which is smaller than said first bird's beak in a side surface of said floating gate.

7. A manufacturing method of a semiconductor device, comprising the steps of:
(a) preparing a semiconductor substrate having a memory cell array region where a first transistor is to be formed, and a peripheral circuit region where a second transistor is to be formed;
(b) forming a first insulating film, a first conductive film, a second insulating film and a second conductive film in this order on an upper surface of said semiconductor substrate in said memory cell array region;
(c) forming a third insulating film and a third conductive film in this order on said upper surface of said semiconductor substrate in said peripheral circuit region;
(d) forming a first film partially on said second conductive film and, also, forming a second film partially on said third conductive film;
(e) removing the portion of said third conductive film which is not covered with said second film, wherein
the portion of said third conductive film which is not removed in said step (e) becomes a gate electrode of said second transistor;
(f) forming a first thermal oxide film having a first bird's beak in a side surface of said gate electrode;
(g) after completion of said step (f), forming a first sidewall insulating film made of a material having an oxygen blocking property on a side surface of said first film and, also, forming a second sidewall insulating film made of said material on said side surface of said gate electrode;
(h) removing the portions of said first conductive film, said second insulating film and said second conductive film which are not covered with said first sidewall insulating film and said first film, wherein
the portion of said first conductive film which is not removed in said step (h) becomes a floating gate of said first transistor, and the portion of said second conductive film which is not removed in said step (h) becomes a control gate of said first transistor; and
(i) forming a second thermal oxide film having a second bird's beak which is smaller than said first bird's beak in a side surface of said floating gate.

8. The manufacturing method of a semiconductor device according to claim 7, wherein
a third thermal oxide film having a third bird's beak which is smaller than said first bird's beak is additionally formed in a side surface of said control gate in said step (i).

9. A manufacturing method of a semiconductor device, comprising the steps of:
(a) preparing a semiconductor substrate having a memory cell array region where a first transistor is to be formed, a high-voltage system peripheral circuit region where a second transistor driven by a high voltage is to be formed, and a low-voltage system peripheral circuit region where a third transistor driven by a low voltage is to be formed;
(b) forming a first insulating film, a first conductive film and a second insulating film in this order on an upper surface of said semiconductor substrate in said memory cell array region;
(c) forming a third insulating film on said upper surface of said semiconductor substrate in said high-voltage system peripheral circuit region;
(d) forming a fourth insulating film on said upper surface of said semiconductor substrate in said low-voltage system peripheral circuit region;
(e) forming a second conductive film and a fifth insulating film in this order on the entire upper surface of said second to fourth insulating films;
(f) partially removing said second conductive film and said fifth insulating film in said high-voltage system peripheral circuit region, wherein
the portion of said second conductive film which is not removed in said step (f) in said high-voltage system peripheral circuit region becomes a gate electrode of said second transistor;
(g) forming a first thermal oxide film having a first bird's beak in a side surface of said gate electrode;
(h) partially removing said first and second conductive films as well as said second and fifth insulating films in said memory cell array region, wherein
the portion of said first conductive film which is not removed in said step (h) in said memory cell array region becomes a floating gate of said first transistor, and the portion of said second conductive film which is not removed in said step (h) in said memory cell array region becomes a control gate of said first transistor;
(i) partially removing said second conductive film and said fifth insulating film in said low-voltage system peripheral circuit region, wherein
the portion of said second conductive film which is not removed in said step (i) in said low-voltage system peripheral circuit region becomes a gate electrode of said third transistor;
(j) forming a second thermal oxide film having a second bird's beak which is smaller than said first bird's beak in a side surface of said floating gate; and
(k) forming a third thermal oxide film having a third bird's beak which is smaller than said first bird's beak in a side surface of said gate electrode of said third transistor.
